(19) United States
(12) Patent Application Publication
(10) Pub. No.: US 2010/0289553 A1
(43) Pub. Date: Nov. 18, 2010

(54) SEMI-ADAPTIVE VOLTAGE SCALING FOR LOW-ENERGY DIGITAL VLSI-DESIGN

(75) Inventor: Zhenhua Wang, Embrach (CH)

Correspondence Address: SEED INTELLECTUAL PROPERTY LAW GROUP PLLC, 701 FIFTH AVENUE, SUITE 5400, SEATTLE, WA, 98104-7092, US

(73) Assignee: ST-ERICSSON SA, Plan-les-Ouates (CH)

(21) Appl. No.: 12/791,709

(22) Filed: Jun. 1, 2010

Related U.S. Application Data
(63) Continuation of application No. 12/688,540, filed on Jan. 15, 2010, now abandoned.
Application No. 12/688,540 is a continuation-in-part of application No. PCT/IB2008/052834, filed on Jul. 15, 2008.

(30) Foreign Application Priority Data
Jul. 19, 2007 (EP) 07112752.6

(51) Int. Cl. H02J 4/00; H01L 21/66; G05F 1/10

(52) U.S. Cl. 327/512; 323/318; 438/17; 327/540; 257/E21.521

(57) ABSTRACT

A semi-adaptive voltage scaling method and device for determining minimal supply voltages for digital electronic semiconductor circuitry, e.g., microprocessors, of electronic devices under production testing and “real” operating conditions. The SAVS operates in a closed-loop during a production test phase of the circuitry and in an open-loop mode in an application (operation) phase of the semiconductor circuitry. During production testing, a lowermost level of the supply voltage for the semiconductor circuitry is determined at one single defined temperature at which operating specifications of the circuit are met. The lowermost level is stored in a dedicated electronic memory of the circuitry together with temperature dependent parameters. Afterwards, when the digital electronic circuitry is operated in a “real” application, e.g., a mobile phone, the device and method reads the previously measured and proven data from the memory and regenerates the minimum level of supply voltage for the circuitry, taking into account the actual temperature of the application. As a result, the digital semiconductor circuitry in the “real” application is supplied with a minimum level of supply voltage, whereby specified parameters of the circuitry are met. Thus, a power consumption of the circuitry is advantageously reduced to a minimum.

### BACKGROUND

1. Technical Field

The present disclosure relates to a method, a system, and a device with regard to supply voltages for individual digital electronic devices, such as microprocessors.

2. Description of the Related Art

As communication terminals are becoming more sophisticated and feature rich, energy consumption is increasing significantly. Hence, low-energy circuit design has become more important than ever before.

Top-down analysis of cellular phone energy budget reveals that the digital circuitry typically consumes more than one third of the total energy of a cellular phone. Therefore, reducing energy consumption of digital circuits can contribute to overall energy reduction of cellular handsets. The energy consumed by digital circuitry can be divided into three components: dynamic energy, static energy, and short-circuit energy.

In operation the short-circuit energy of properly designed digital circuits is negligible compared to dynamic energy due to charging of capacitances, whereas leakage energy is dominant when the circuits are idle. Dynamic energy can be reduced proportionally by reducing the activity factor, the load capacitance, and the clock frequency. Yet the most effective approach often is to reduce the supply voltage. However, when transistor drive current is reduced at lower supply voltage, leading to lower circuit speed and as a result, performance goals such as throughput may not be met. A possible way to maintain the same drive current is to lower the transistor threshold voltage. Unfortunately, this would make noise margin worse and increase sub-threshold leakage current, which is often the major contributor to total leakage.

In general, supply voltage-scaling schemes for digital electronic circuits are well known, for example, Adaptive Voltage Scaling (AVS) and Dynamic Voltage Scaling (DVS). The main principle of such scaling schemes is an adaptation of a supply voltage level in dependence of differing production process-tolerances of each individual circuit and the actual operation temperature. One known AVS scheme is known as “PowerWise,” which is described for instance in M. Hartman, “PowerWise adaptive voltage scaling minimizes energy consumption,” Information Quarterly, vol. 3, no. 1, pp. 27-29, 2004 (in the following Hartman, for short).

WO 2006/010988 proposes a model for determining of a supply voltage level for operating an integrated circuit. In this model for an exact voltage level calibration it is proposed: to provide a high load condition to an integrated circuit, to adjust a first voltage level of the integrated circuit to provide a stable operation of the integrated circuit in the high load condition, to measure a temperature of the integrated circuit in the high load condition, to store the measured temperature in the high load condition, and to store the adjusted first voltage level in the high load condition. Basically, an interpolation-type approach is implemented, which is based on the information acquired by an on-chip voltage dependent delay monitor and temperature sensor, under two extreme conditions: a first extreme condition is a so-called ‘artificial system operation’ defined by minimum load and minimum supply voltage, at a certain defined low temperature, the second extreme condition is defined by maximum load, maximum supply voltage, at a certain predefined high temperature. Having acquired this information at these extreme conditions, the proposed model assumes the suitable supply voltage in normal operation to be somewhere in between these known two extremes, which is then calculated accordingly.

### BRIEF SUMMARY

The present disclosure relates to a method, a system, and a device for determining of information with regard to minimal supply voltages for individual digital electronic devices, such as microprocessors, under production testing. Further, the present disclosure relates to a method, a system, and a device providing for self-adjusting of the supply voltage at a respective minimal supply voltage for the individual digital electronic device under real operating conditions based on the determined information during production testing.

Summarizing WO 2006/010988, the applied interpolation is based on the two measured voltage levels, which are used for calibration and which are fixed and predefined for all devices of each design. However, the ideal minimal supply voltage is not known beforehand and differs from device to device. Furthermore, the two temperatures in WO 2006/010988 are predefined and calibration must be done at more or less exactly these temperatures. Moreover, the calibration procedure must be done at these two predefined temperatures: Firstly, at a lower and at a higher temperature, which causes time delay until the higher temperature is reached, thus losing much valued time for calibration. This is because operation can only start after the calibration has completed. Other prior art AVS systems have similar or other drawbacks, in particular very high complexity, being prone to instability, and longer settling times, just to mention a few.

An embodiment provides an improved system, circuitry, and method for providing the possibility to have the supply voltage of a digital electronic semiconductor circuitry, such as microprocessors, adjusted to respective suitable minimal supply voltage for operating conditions, preferably in an automatic manner.

In an embodiment, a system, circuitry, and method determine information with regard to minimal supply voltage for a digital electronic semiconductor circuitry in production testing. In an embodiment, a system, circuitry, and method adjust the supply voltage to a respective suitable minimal supply voltage for the individual digital electronic device in operation or application under “real” operating conditions based on the determined information during the production testing.

In an embodiment, an electronic circuit is presented for determining a minimal supply voltage for a semiconductor circuitry during production and for self-adjusting the supply voltage to a respective minimal supply voltage in operation thereof, wherein the electronic circuit comprises:

memory means with stored information related to at least one offset voltage and at least one temperature related parameter, which identify the minimal supply voltage for the semiconductor circuitry at the testing temperature, and

reference voltage means for producing a reference voltage corresponding to the minimal supply voltage at the actual operating temperature;

wherein information related to at least one offset voltage and at least one temperature related parameter, which identify the minimal supply voltage for the semiconductor circuitry at an arbitrary testing temperature, which information was determined in a closed-loop configuration at the testing temperature such that to meet a determined test of the semiconductor circuitry.

In an embodiment, a testing unit is presented for determining a minimal supply voltage for a semiconductor circuitry during production thereof, wherein the testing unit comprises:

an adjustable offset voltage source and a offset voltage terminal for supplying an offset voltage; and

control interface for connection to the semiconductor circuitry and for control of a determined test of the semiconductor circuitry;

wherein the testing unit is arranged to determine in a closed-loop configuration the minimal supply voltage for the semiconductor circuitry at the testing temperature such that determined operating specifications of the semiconductor circuitry are met and to store information relating to at least one offset voltage and at least one temperature dependent parameter, which correspond to a minimal supply voltage at a testing temperature, and

wherein in the closed-loop configuration the testing unit is connected to an electronic circuit via the offset voltage terminal to the electronic circuit, and

wherein the testing unit is configured to receive via the control interface information on the determined test and to control via the control interface the determined test for the semiconductor circuitry and to adjust the offset voltage until the determined test passed, thereby determining the minimal supply voltage.

In an embodiment, a method is presented for determining a minimal supply voltage for an individual semiconductor circuitry during production thereof, wherein the method comprises:

determining information related to at least one offset voltage and at least one temperature related parameter, which identify the minimal supply voltage for the semiconductor circuitry at the testing temperature such that to meet a determined test of the semiconductor circuitry; and

storing the information related to the at least one offset voltage and the at least one temperature related parameter in an electronic memory of the semiconductor circuitry.

In an embodiment, a method is presented for adjusting a supply voltage for an individual semiconductor circuitry to a minimal supply voltage during operation thereof, wherein the method comprises:

reading stored information related to at least one offset voltage and at least one temperature related parameter, which identify the minimal supply voltage from an electronic memory of the semiconductor circuitry, measured and stored during production test of the semiconductor circuitry at the testing temperature; and

regenerating the minimal supply voltage for the semiconductor circuitry according to the actual temperature in the application.

In an embodiment, a system is presented for determining a minimal supply voltage for a semiconductor circuitry during production thereof, wherein the system comprises:

the semiconductor circuitry;

an electronic circuit having memory means for storing information related to at least one offset voltage and at least one temperature related parameter, which identify the minimal supply voltage for the semiconductor circuitry at the testing temperature, and reference voltage means for producing a reference voltage corresponding to the minimal supply voltage at the testing temperature; and

a testing unit arranged,

to determine the minimal supply voltage for the semiconductor circuitry at the testing temperature in a closed-loop configuration such that a determined test for the semiconductor circuitry is passed, and

to store the information related to the minimal supply voltage into the memory means;

wherein the testing unit is connectable with the electronic circuit and the semiconductor circuit in the closed-loop configuration, and the testing unit is configured to control the determined test for the semiconductor circuitry, to select the at least one temperature related parameter and to adjust the offset voltage of the reference voltage until the determined test for the semiconductor circuitry is passed, thereby determining the minimal supply voltage.

In an embodiment, a system is presented for self-adjusting a supply voltage to a minimal supply voltage for a semiconductor circuitry during operation thereof, wherein the system comprises:

the semiconductor circuitry;

an electronic circuit having memory means for storing information related to at least one offset voltage and at least one temperature related parameter, which identify the minimal supply voltage for the semiconductor circuitry at the testing temperature, and reference voltage means for producing a reference voltage comprised of the offset voltage and a variable voltage which is arranged as self-adjusting according to the at least one temperature related parameter in relation to a difference of the actual temperature to the testing temperature; and

a power management unit arranged to regenerate the respective minimal supply voltage for the semiconductor circuitry in accordance with the reference voltage;

wherein the power management unit is connected with the electronic circuit and the semiconductor circuit in a open-loop configuration.

In some embodiments, there is a low-voltage source with a determined temperature coefficient corresponding to the at least one temperature related parameter, which low-voltage source is configured to provide a temperature proportional low-voltage.

In an embodiment, the low-voltage source comprises a current source providing a temperature related current, which is proportional to the absolute temperature. Furthermore, the low-voltage source can further comprise selecting means for selecting a respective temperature coefficient for the temperature related current provided by the current source. In an embodiment, the temperature may be selected from a set of determined temperatures. Moreover, the selecting means may comprise selectable switching means for selecting one of several temperature coefficients, wherein selecting means are configured to be selectable in accordance with the stored information on the at least one temperature related parameter. There may be also converting means for converting the temperature related current provided by the current source into a respective temperature related voltage.

In one embodiment, there may an adjustable voltage source for providing the at least one offset-voltage in accordance with the respective stored information. In an embodiment, the offset-voltage source comprises a determined output voltage range, which is adjustable in voltage steps, wherein the offset-voltage source is configured such that each output voltage of the output voltage range is selectable by the respective stored information.

In an embodiment, the stored information on the at least one offset-voltage and the at least one temperature related parameter are respective binary coded information, which is stored in the memory of the electronic circuit for later use in operation of the electronic circuit.

Also, in certain embodiments, there are adding means for adding the at least one offset voltage to the low-voltage for producing of the reference voltage.

In an embodiment, there may by an internal or external, i.e., separate, supply voltage source providing a controlled supply voltage corresponding to the semiconductor circuitry based on the reference voltage.

In an embodiment, determining the minimal supply voltage may comprise:
selecting a low-voltage source with a determined temperature coefficient corresponding to the at least one temperature related parameter, which low-voltage source provides a temperature proportional low-voltage;
adding the at least one offset voltage to the low-voltage for producing of a reference voltage; and
generating a corresponding supply voltage for the semiconductor circuitry based on the reference voltage.

In an embodiment, determining the minimal supply voltage might be performed in a closed-loop configuration comprising the step of producing of the reference voltage and the step of generating of the supply voltage, by adjusting of the offset voltage until a test for the semiconductor circuitry is passed. In an embodiment, the step is a determined test.

In an embodiment, the step of storing information related to the at least one offset voltage and the at least one temperature related parameter may comprise:
storing parameter values for identifying the selected low-voltage source and the offset voltage.

In an embodiment, the step of determining the minimal supply voltage further may comprise:
outputting the reference voltage to a testing unit,
generating the supply voltage based on the reference voltage; and
supplying the generated supply voltage to the semiconductor circuitry by the testing unit or a separate voltage supply unit.

In an embodiment, the step of generating the supply voltage for the semiconductor circuitry based on the reference voltage may comprise:
multiplying the produced reference voltage by a control factor. In an embodiment, the control factor may be predefined or selected from a set of defined control factors.

In an embodiment, the step of reading stored information related to the at least one offset voltage and the at least one temperature related parameter may comprise:
retrieving parameter values for identifying a low-voltage source with a temperature coefficient corresponding to the at least one temperature related parameter and the offset voltage; and
adding the offset voltage to the low-voltage to produce the reference voltage.

In an embodiment, the step of regenerating the minimal supply voltage further may comprise:
minimizing the reference voltage in an open-loop configuration comprised of the step of producing the reference voltage and the step of generating the supply voltage, by adjusting the low-voltage in relation to a difference of the actual temperature in the application and the testing temperature in production testing such that a test of the semiconductor circuitry is met.

In an embodiment, the step of regenerating the minimal level of supply voltage further may comprise:
applying the reference voltage to an on-chip or off-chip power management unit for generating the minimal supply and supplying the minimal supply to the semiconductor circuitry.

It is to be noted that the testing temperature may be, basically, an arbitrary temperature, which is may be higher than normal ambient temperature, but which needs not necessarily be a maximum allowable temperature for the semiconductor circuitry. In other words, the minimal supply voltage resumes the same value as once determined during production of the semiconductor circuitry, if the electronic device is the same temperature in operation as during determining during production of the semiconductor circuitry.

Moreover, it is worth noting that the determining of the information related to the at least one offset voltage and the at least one temperature related parameter, can be done alternatively or even additionally during an end testing when packaging of the electronic circuit in production takes place. Furthermore, the memory for storage of the information related to the at least one offset voltage and the at least one temperature related parameter may be implemented as changeable or re-writable, respectively, such that the stored information may also be amended if necessary.

For instance, the temperature during wafer testing may be used, where the wafer is heated to have a higher temperature then the normal ambient room temperature, e.g., 27° C. In addition, during packaging of the electronic circuit the temperature is around ambient room temperature. In addition, it may be possible to enable some kind of reprogramming of the information related to the at least one offset voltage and the at least one temperature related parameter in application of the electronic circuit, if desired for some reason.

In this context, it is noted that all aspects of the concept discussed hereinabove, can be extended for multiple-frequency operating frequencies of the electronic circuit. For example, a respective extension of the memory may be implemented for storing the respective information related to the at least one offset voltage and the at least one temperature related parameter at the different operation frequencies of the electronic circuit.

An embodiment has a closed-loop mode during a production test phase of an electronic circuitry and an open-loop mode in an application phase, i.e., in operation, of the circuitry. During the production test, a lowermost level of the supply voltage is determined for the semiconductor circuitry at one single defined temperature, at which supply voltage all operating specifications of the circuit are fully met. The lowermost voltage level is stored in the electronic circuitry, e.g., in a dedicated electronic memory, together with temperature dependent parameters. Afterwards, in operation of the electronic circuitry, i.e., in a “real” application such as a mobile electronic device such as a mobile phone, personal digital assistant, laptop and so on, the previously measured and tested data can be retrieved from the memory and the minimum level of supply voltage for the circuitry can be regenerated under consideration of the actual temperature of the “real” application. As a result, the semiconductor circuitry in the “real” application can be supplied with a minimum level of supply voltage, whereby all specified parameters of the circuitry are fully met. Thus, a power consumption of the circuitry is advantageously reduced.

Accordingly, disadvantages of prior art AVS systems of very high complexity, being prone to instability, having higher settling times can be avoided. An embodiment enables an effective way of power saving of electronic circuitry much easier and cheaper than conventional systems.

In an embodiment, an electronic circuit for determining a minimal supply voltage (Vₛᵤₚⱼ) for a semiconductor circuitry during production and for self-adjusting the supply voltage to a respective minimal supply voltage in operation thereof, comprises: a memory configured to store information related to at least one offset voltage (V_{DCj}) and at least one temperature related parameter, which identify the minimal supply voltage (Vsuppj) for the semiconductor circuitry at the testing temperature (Tₜₑₛₜ); and a reference voltage means for producing a reference voltage (V_{refj}) corresponding to the minimal supply voltage (Vₛᵤₚⱼ) at the actual operating temperature (Tₐₚₚₗ), wherein information related to at least one offset voltage (V_{DCj}) and at least one temperature related parameter identify the minimal supply voltage (Vₛᵤₚⱼ) for the semiconductor circuitry at an arbitrary testing temperature, which information was determined in a closed-loop configuration at the testing temperature such that to meet a predetermined test of the semiconductor circuitry. An embodiment further comprises a low-voltage source with a predetermined temperature coefficient corresponding to the at least one temperature related parameter, which low-voltage source is configured to provide a temperature proportional low-voltage (V_{TCj}). In an embodiment, the low-voltage source comprises a current source (PTAT) providing a temperature related current, which is proportional to the absolute temperature. In an embodiment, the low-voltage source further comprises selecting means for selecting a respective predetermined temperature coefficient (TC1, TC2, TC3/4, TC5) for the temperature related current provided by the current source (PTAT). In an embodiment, the selecting means comprises selectable switching means (SW) for selecting one of several predetermined temperature coefficients (TC1, TC2, TC3/4, TC5), wherein selecting means are configured to be selectable in accordance with the stored information on the at least one temperature related parameter. An embodiment further comprises converting means (R2) for converting the temperature related current (I_{PTAT, TCj}) provided by the current source (PTAT) into a respective temperature related voltage (V_{TCj}). An embodiment further comprises: an adjustable voltage source for providing the at least one offset-voltage (V_{DCj}) in accordance with the respective stored information. In an embodiment, the offset-voltage source comprises a predetermined output voltage range (V_{ref,min}−V_{ref, max}), which is adjustable in predetermined voltages steps, wherein the offset-voltage source is configured such that each output voltage of the output voltage range is selectable by the respective stored information. In an embodiment, the stored information on the at least one offset-voltage and the at least one temperature related parameter are respective binary coded information (V_{DC0}, TCS, M0 . . . M7). In an embodiment, the electronic circuit further comprises adding means for adding the at least one offset voltage (V_{DCj}) to the low-voltage (V_{TCj}) for producing of the reference voltage (V_{refj}). In an embodiment, the electronic circuit further comprises: a supply voltage source providing a controlled supply voltage for the semiconductor circuitry based on the reference voltage (V_{refj}).

In an embodiment, a testing unit for determining a minimal supply voltage for a semiconductor circuitry during production thereof, comprises: an adjustable offset voltage source and a offset voltage terminal for supplying an offset voltage (V_{DCj}); and control interface for connection to the semiconductor circuitry and for control of a predetermined test of the semiconductor circuitry; wherein the testing unit is arranged to determine in a closed-loop configuration the minimal supply voltage for the semiconductor circuitry at the testing temperature such that predetermined operating specifications of the semiconductor circuitry are met and to store information on at least one offset voltage and at least one temperature dependent parameter which correspond to a minimal supply voltage at a testing temperature, and wherein in the closed-loop configuration the testing unit is connected to an electronic circuit via the offset voltage terminal to the electronic circuit, and the testing unit is configured to receive via the control interface information on the predetermined test and to control via the control interface the predetermined test for the semiconductor circuitry and to adjust the offset voltage (V_{DCj}) until the predetermined test is passed, thereby determining the minimal supply voltage.

In an embodiment, a method for determining a minimal supply voltage (Vₛᵤₚⱼ) for an individual semiconductor circuitry during production thereof, comprises: determining information related to at least one offset voltage (V_{DCj}) and at least one temperature related parameter, which identify the minimal supply voltage (Vₛᵤₚⱼ) for the semiconductor circuitry at the testing temperature such that to meet a predetermined test of the semiconductor circuitry; and storing the information related to the at least one offset voltage (V_{DCj}) and the at least one temperature related parameter in an electronic memory of the semiconductor circuitry. In an embodiment, determining the minimal supply voltage (Vₛᵤₚⱼ) may comprise: selecting a low-voltage source (V_{TCj}) with a predetermined temperature coefficient corresponding to the at least one temperature related parameter, which low-voltage source providing a temperature proportional low-voltage (V_{TCj}); adding the at least one offset voltage to the low-voltage for producing of a reference voltage (V_{refj}); and generating a corresponding supply voltage (Vₛᵤₚⱼ) for the semiconductor circuitry based on the reference voltage (V_{refj}). In an embodiment, determining the minimal supply voltage (Vₛᵤₚⱼ) is performed in a closed-loop configuration comprised of the step of producing of the reference voltage (V_{refj}) and the step of generating of the supply voltage (Vₛᵤₚⱼ), by adjusting of the offset voltage (V_{DCj}) until a predetermined test for the semiconductor circuitry is passed. In an embodiment, storing information related to the at least one offset voltage (V_{DCj}) and the at least one temperature related parameter may comprise: storing parameter values for identifying the selected low-voltage source (V_{TCj}) and the offset voltage (V_{DCj}). In an embodiment, the testing temperature is an arbitrary temperature, which is higher than normal ambient temperature, but which is not necessarily a maximum allowable temperature for the semiconductor circuitry. In an embodiment, determining the minimal supply voltage (V_{TCj}) further may comprise: outputting the reference voltage (V_{refj}) to a testing unit; generating the supply voltage (Vₛᵤₚⱼ) based on the reference voltage (V_{refj}); and supplying the generated supply voltage (Vₛᵤₚⱼ) to the semiconductor circuitry by the testing unit or a separate voltage supply unit. In an embodiment, the method comprises generating the supply voltage (Vₛᵤₚⱼ) for the semiconductor circuitry based on the reference voltage (V_{refj}): and multiplying the produced reference voltage (V_{refj}) by a predefined control factor (β).

In an embodiment, a method for adjusting a supply voltage for an individual semiconductor circuitry to a minimal supply voltage (Vₛᵤₚⱼ) during operation thereof, comprises: reading stored information (V_{DC0}, TCS) related to at least one offset voltage (V_{DCj}) and at least one temperature related parameter, which identify the minimal supply voltage (Vₛᵤₚⱼ) from an electronic memory of the semiconductor circuitry, measured and stored during production of the semiconductor circuitry at the testing temperature; and regenerating the minimal supply voltage (V_{DCj}) for the semiconductor circuitry based on the actual temperature in the application. In an embodiment, reading stored information (V_{DC0}, TCS) related to the at least one offset voltage (V_{DCj}) and the at least one temperature related parameter may comprise: retrieving parameter values (TCS) for identifying a low-voltage source (V_{TCj}) with a predetermined temperature coefficient (TC) corresponding to the at least one temperature related parameter and the offset voltage (V_{DCj}); and adding the offset voltage (V_{DCj}) to the low-voltage (V_{TCj}) to produce the reference voltage (V_{refj}). In an embodiment, regenerating the minimal supply voltage (Vₛᵤₚⱼ) further may comprise: minimizing the reference voltage (V_{refj}) in an open-loop configuration comprised of the step of producing the reference voltage (V_{refj}) and the step of generating the supply voltage (Vₛᵤₚⱼ), by adjusting the low-voltage (V_{TCj}) in relation to a difference of the actual temperature (Tₐₚₚₗ) in the application and the testing temperature (Tₜₑₛₜ) in production testing such that a predetermined test of the semiconductor circuitry is met. In an embodiment, regenerating the minimal level of supply voltage (Vₛᵤₚⱼ) further comprises: applying the reference voltage (V_{refj}) to an on-chip or off-chip power management unit for generating the minimal supply (Vₛᵤₚⱼ) and supplying the minimal supply voltage (Vₛᵤₚⱼ) to the semiconductor circuitry. In an embodiment, the minimal supply voltage (Vₛᵤₚⱼ) resumes the same value as once determined during production of the semiconductor circuitry, if the electronic circuit has the same temperature as during determining during production of the semiconductor circuitry.

In an embodiment, a system for determining a minimal supply voltage (Vₛᵤₚⱼ) for a semiconductor circuitry during production thereof, comprises: the semiconductor circuitry; an electronic circuit having memory means for storing information (V_{DC0}, TCS) related to at least one offset voltage (V_{DCj}) and at least one temperature related parameter, which identify the minimal supply voltage (Vₛᵤₚⱼ) for the semiconductor circuitry at the testing temperature (Tₜₑₛₜ), and reference voltage means for producing a reference voltage (V_{refj}) corresponding to the minimal supply voltage (Vₛᵤₚⱼ) at the testing temperature (Tₜₑₛₜ); and a testing unit arranged to: determine the minimal supply voltage (Vₛᵤₚⱼ) for the semiconductor circuitry at the testing temperature (Tₜₑₛₜ) in a closed-loop configuration such that a predetermined test for the semiconductor circuitry is passed; and to store the information related to the minimal supply voltage into the memory means together with at least one temperature related parameter; wherein the testing unit is connectable with the electronic circuit and the semiconductor circuit in the closed-loop configuration, and the testing unit is configured to control the predetermined test for the semiconductor circuitry, to select the at least one temperature related parameter (TC) and to adjust an offset voltage (V_{DCj}) of the reference voltage (V_{refj}) until the predetermined test for the semiconductor circuitry is passed, thereby determining the minimal supply voltage (Vₛᵤₚⱼ).

In an embodiment, a system for self-adjusting a supply voltage to a minimal supply voltage (Vₛᵤₚⱼ) for a semiconductor circuitry during operation thereof, comprises: the semiconductor circuitry; an electronic circuit having memory means for storing information related to at least one offset voltage (V_{DCj}) and at least one temperature related parameter, which identify the minimal supply voltage (Vₛᵤₚⱼ) for the semiconductor circuitry at the testing temperature (Tₜₑₛₜ), and reference voltage means (214) for producing a reference voltage (V_{refj}) comprised of the offset voltage (V_{DCj}) and a variable voltage (V_{TCj}) which is arranged as self-adjusting according to the at least one temperature related parameter (TC) in relation to a difference of the actual temperature (Tₐₚₚₗ) to the testing temperature (Tₜₑₛₜ); and a power management unit arranged to regenerate the respective minimal supply voltage (Vₛᵤₚⱼ) for the semiconductor circuitry in accordance with the reference voltage (V_{refj}), wherein the power management unit is connected with the electronic circuit and the semiconductor circuitry in a open-loop configuration.

In an embodiment, a low-voltage source for providing a temperature related voltage (V_{TCj}) having a selectable temperature coefficient (TC1, TC2, TC3/4, TC5), comprises: a current source section (PTAT) for generating a temperature related current which is proportional to the absolute temperature, in which a first transistor (M1) and a second transistor (M2) configured to operate in weak inversion are each respectively connected to a third transistor (M3) and a fourth transistor (M4) of a first current mirror (CM1), which are configured to operate in saturation region; a second current mirror (CM2) comprised of a fifth transistor (M5) and sixth transistor (M6), which second current mirror (CM2) is selectable coupleable via one of a group of coupling transistors (Mff, Mfs, Msf_n, Mss) to the first current mirror (CM1) of the current source section (PTAT), wherein the coupling transistors (Mff, Mfs, Msf_n, Mss) are configured to provide in accordance with the temperature related current of the current source section (PTAT) a temperature related current with a predetermined temperature coefficient (TC1, TC2, TC3/4, TC5); switching means (SW) configured for connecting one of the group of coupling transistors (Mff, Mfs, Msf_n, Mss) in accordance with an external selection signal to the input current path of the second current mirror (CM2); and a predetermined output resistor means (R2) connected to the output current path of the second current mirror (CM2) such that the temperature related voltage (V_{TCj}) is provided as voltage drop at the output resistor means (R2). In an embodiment, the first and second current mirror (CM1, CM2) are configured to have unity current ratio. In an embodiment, the switching means (SW) for connecting a respective coupling transistor (Mff, Mfs, Msf_n, Mss) comprises switches (1, 2, 3/4, 5), realized by respective switching transistors, and wherein the coupling transistor (Mff, Mfs, Msf_n, Mss) have different aspect ratios (A1, A2, A3, A4) for implementing the different temperature coefficients (TC1, TC2, TC3/4, TC5).

In an embodiment, a voltage adder for adding a first and a second input voltage and providing inherent buffering and/or driving capability, comprises: an operational amplifier (A2) section having an inverting input and a non-inverting input, an output for outputting an output voltage, wherein a predetermined feedback resistor (R2) is connected to the inverting input and the output of the operational amplifier (A2), wherein the first input voltage (V_{DCj}) is to be applied to the non-inverting input of operational amplifier (A2), and the second input voltage (V_{TCj}) is to be generated as voltage drop over the feedback resistor (R2) by a respective current (I_{PTAT}, TCⱼ), such that the sum of the first input voltage (V_{DCj}) and second input voltage (V_{TCj}) appears at the output of the operational amplifier (A2).

In an embodiment, an adjustable voltage source, based on a digital-to-analog converter having a gain stage with a resistor ladder (RL) as resolution step generating unit for an output voltage of the voltage source, comprises an operational amplifier (A1) connected with a resistor ladder (RL) being a series connection of a predetermined number of resistors (R), a first end of which resistor ladder (RL) being connected with an output of the operational amplifier (A1), a second end of which resistor ladder (RL) being connected to ground, and one of the interconnection points between the resistors (R) of the resistor ladder (RL) being connected to an inverting input of operational amplifier (A1) such as to form a non-inverting amplifier configuration, wherein the resistor ladder (RL) further provides the adjustable output voltage in respective voltage steps generated by series connection of the resistors of the resistor ladder (RL), and wherein switching means are provided, which are configured to selectably connect one of the interconnection points of the resistor ladder (RL) with the output of the adjustable voltage source, such that in the adjustable voltage source simultaneously a DC gain of the operational amplifier (A1) is set by means of the resistor ladder (RL) and the output voltage of the operational amplifier (A1) is subdivided in respective steps at the resistor ladder (RL).

In an embodiment, an electronic device comprises: a memory configured to store information related to at least one offset voltage and at least one temperature-related parameter, which identify a minimal supply voltage for a semiconductor circuit at a testing temperature in a closed-loop configuration that satisfies test conditions; and a reference voltage generator configured to generate a reference voltage corresponding to a supply voltage at an actual operating temperature based on the stored information and the actual operating temperature. In an embodiment, the device further comprises: a low-voltage source with a temperature coefficient corresponding to the at least one temperature related parameter, and configured to provide a temperature proportional low-voltage. In an embodiment, the low-voltage source comprises a current source providing a temperature-related current, which is proportional to an absolute temperature. In an embodiment, the low-voltage source comprises: a current source section configured to generate a first temperature-related current which is proportional to an absolute temperature, having a first transistor and a second transistor configured to operate in weak inversion and connected to a third transistor and a fourth transistor of a first current mirror, the third and fourth transistors configured to operate in a saturation region; a second current mirror having a fifth transistor and sixth transistor, wherein the second current mirror is selectable coupleable via one of a group of coupling transistors to the first current mirror of the current source section and the coupling transistors are configured to provide a second temperature-related current based on the first temperature-related current, the second temperature-related current having one of a set of different temperature coefficients; a switch configured to connect one of the group of coupling transistors to an input current path of the second current mirror based on a selection signal; and an output resistor coupled to an output current path of the second current mirror such that a temperature related voltage is provided as voltage drop across the output resistor. In an embodiment, the first and second current mirrors are configured to have a unity current ratio. In an embodiment, the switch comprises respective switching transistors coupled to the coupling transistors, and wherein the coupling transistors have different aspect ratios for implementing the set of different temperature coefficients. In an embodiment, the low-voltage source further comprises a selector configured to select a respective temperature coefficient based on the temperature-related current provided by the current source. In an embodiment, the selector comprises selectable switches configured to select one of several determined temperature coefficients based on the at least one temperature-related parameter. In an embodiment, the device further comprises a converter configured to convert the temperature-related current provided by the current source into a respective temperature-related voltage. In an embodiment, the device further comprises: an adjustable voltage source configured to provide the at least one offset-voltage. In an embodiment, the adjustable voltage source has an output voltage range which is adjustable in voltages steps, and is configured such that each output voltage of the output voltage range is selectable based on the stored information. In an embodiment, the adjustable voltage source comprises: a digital-to-analog converter having: an operational amplifier; a resistor ladder comprising a series connection of a number of resistors, a first end of the resistor ladder being connected with an output of the operational amplifier, a second end of the resistor ladder being connected to ground, and one of the interconnection points between the resistors of the resistor ladder being connected to an inverting input of operational amplifier such as to form a non-inverting amplifier configuration; and a switch configured to selectively connect one of the interconnection points of the resistor ladder to an output of the adjustable voltage source. In an embodiment, the stored information on the at least one offset-voltage and the at least one temperature related parameter are respective binary coded information. In an embodiment, the device further comprises: a voltage adder configured to add the at least one offset voltage to the low-voltage to produce the reference voltage. In an embodiment, the voltage adder comprises: an operational amplifier section having an inverting input and a non-inverting input, an output for outputting an output voltage, and a feedback resistor connected to the inverting input and the output of the operational amplifier, wherein the at least one offset voltage is applied to the non-inverting input of operational amplifier, and the low voltage is generated as voltage drop over the feedback resistor by a respective current such that a sum of the at least one offset voltage and the low voltage appears at the output of the operational amplifier. In an embodiment, the device further comprises: a supply voltage source configured to provide a controlled supply voltage for the semiconductor circuit based on the reference voltage.

In an embodiment, a testing unit comprises: an adjustable offset voltage source having an offset voltage terminal configured to supply an offset voltage; and a controller configured to interface with semiconductor circuitry and an electronic circuit, to control a test of the semiconductor circuitry in a closed-loop configuration to determine a minimal supply voltage for the semiconductor circuitry at a testing temperature such that operating specifications of the semiconductor circuitry are met, and to store information in the electronic circuit indicative of at least one offset voltage and at least one temperature dependent parameter which correspond to the minimal supply voltage at the testing temperature, wherein in the closed-loop configuration the testing unit is coupled to the electronic circuit via the offset voltage terminal and via the semiconductor circuitry, and the testing unit is configured to receive information on the test and to adjust the offset voltage until the test is passed, thereby determining the minimal supply voltage.

In an embodiment, a method comprises: during fabrication of a semiconductor circuit, determining information related to at least one offset voltage and at least one temperature-related parameter, which identify a minimal supply voltage for the semiconductor circuit at a testing temperature satisfying a testing criteria of the semiconductor circuit; and storing the information related to the at least one offset voltage and the at least one temperature-related parameter in a memory of the semiconductor circuit. In an embodiment, the step of determining comprises: selecting a low-voltage source with a temperature coefficient corresponding to the at least one temperature-related parameter, the low-voltage source providing a temperature proportional low-voltage; adding the at least one offset voltage to the low-voltage to produce a reference voltage; and generating a corresponding supply voltage for the semiconductor circuit based on the reference voltage. In an embodiment, the step of determining is performed in a closed-loop configuration and comprises producing of the reference voltage and generating the supply voltage by adjusting the offset voltage until a test for the semiconductor circuit is passed. In an embodiment, the step of storing information related to the at least one offset voltage and the at least one temperature related parameter comprises: storing parameter values for identifying a selected low-voltage source and the offset voltage. In an embodiment, the testing temperature is an arbitrary temperature, which is higher than a normal ambient temperature. In an embodiment, the arbitrary temperature is less than a maximum allowable temperature of the semiconductor circuit. In an embodiment, the step of determining comprises: outputting the reference voltage to a testing unit; generating the supply voltage based on the reference voltage; and supplying the generated supply voltage to the semiconductor circuit through one of the testing unit or a separate voltage supply unit. In an embodiment, the step of generating the supply voltage for the semiconductor circuitry based on the reference voltage comprises: multiplying the produced reference voltage by a control factor.

In an embodiment, a method comprises: reading from a memory stored information related to at least one offset voltage and at least one temperature-related parameter, which identify a minimal test supply voltage of a semiconductor circuit, measured and stored during production of the semiconductor circuit at a testing temperature; and generating a minimal operational supply voltage for the semiconductor circuitry based on an actual temperature in an application and the stored information. In an embodiment, the step of reading stored information related to the at least one offset voltage and the at least one temperature related parameter comprises retrieving parameter values for identifying a low-voltage source with a temperature coefficient corresponding to the at least one temperature-related parameter and the offset voltage, and the method comprises adding the offset voltage to a low-voltage provided by the low-voltage source to produce a reference voltage. In an embodiment, the minimal test supply voltage corresponds to a voltage at which a testing criteria is satisfied and the step of generating the minimal operational supply voltage comprises: minimizing the reference voltage in an open-loop configuration by adjusting the low-voltage based on a difference between the actual temperature in the application and the testing temperature in production. In an embodiment, the step of generating the minimal operational supply voltage further comprises: applying the reference voltage to an on-chip or off-chip power management unit for generating the minimal operational supply voltage and supplying the minimal operational supply voltage to the semiconductor circuitry. In an embodiment, the minimal operational supply voltage is equal to the minimal test supply voltage when the actual temperature is equal to the testing temperature.

In an embodiment, a system comprises: semiconductor circuitry; an electronic circuit having a memory configured to store information related to at least one offset voltage and at least one temperature-related parameter, which identify a minimal supply voltage for the semiconductor circuitry at a testing temperature, and a reference voltage generator configured to produce a reference voltage corresponding to the minimal supply voltage at the testing temperature; and a testing unit configured to: determine the minimal supply voltage for the semiconductor circuitry at the testing temperature in a closed-loop configuration such that a test for the semiconductor circuitry is passed; and store the information related to the minimal supply voltage into the memory together with the at least one temperature-related parameter wherein the testing unit is connectable to the electronic circuit and the semiconductor circuitry in the closed-loop configuration, and the testing unit is configured to control the test for the semiconductor circuitry, to select the at least one temperature-related parameter and to adjust the at least one offset voltage of the reference voltage until the test for the semiconductor circuitry is passed, thereby determining the minimal supply voltage.

In an embodiment, a system comprises: semiconductor circuitry; an electronic circuit having a memory configured to store information related to at least one offset voltage and at least one temperature-related parameter, which identify a minimal supply voltage for the semiconductor circuitry at a testing temperature and a reference voltage generator configured to produce a reference voltage comprised of the at least one offset voltage and a variable voltage which is based on the at least one temperature-related parameter and a difference between an actual temperature and the testing temperature; and a power management unit generate a minimal operational supply voltage for the semiconductor circuitry based on the reference voltage, wherein the power management unit is connected with the electronic circuit and the semiconductor circuitry in a open-loop configuration.

In an embodiment, a system comprises: semiconductor circuitry; means for storing information related to at least one offset voltage and at least one temperature-related parameter, which identify a minimal supply voltage for the semiconductor circuitry at a testing temperature; means for generating a reference voltage comprised of the at least one offset voltage and a variable voltage which is based on the at least one temperature-related parameter and a difference between an actual temperature and the testing temperature; and means for generating a minimal operational supply voltage for the semiconductor circuitry in an open-loop configuration based on the reference voltage.

### BRIEF DESCRIPTION OF THE SEVERAL VIEWS OF THE DRAWINGS

These and other aspects of this disclosure will be apparent from and elucidated with reference to the embodiment(s) described hereinafter with reference to the following drawings, in which:

FIG. 1 depicts a prior art AVS, wherein the APC can set the correct operating voltage in either an open-loop or a closed-loop mode;

FIG. 2a shows a schematic basic block diagram of an embodiment of an SAVS system according to the present disclosure during production test;

FIG. 2b shows a schematic basic block diagram of an embodiment of an SAVS system according to the present disclosure in application;

FIG. 2c is a simplified flow diagram illustrating the steps of an embodiment of a method of configuring an SAVS system in production of an electronic device and later an embodiment of a self-adjusting function of an SAVS in application of the electronic device;

FIG. 3 is a more detailed block diagram of one embodiment of an SAVS;

FIG. 4 is a TCGs schematic with merged TCS providing 5 different and selectable TCs corresponding to 4 process corners and nominal process;

FIG. 5 illustrates a simulated value of V_{DCj} and αᵢ for four process corners plus nominal process;

FIG. 6 shows an example for an implementation of an efficient DAC with merged gain stage and resistor ladder capable of delivering an output level higher than the input reference, which can be used in implementation of the SAVS according to an embodiment; and

FIG. 7 illustrates gate delay against supply voltage, actual temperature, and process parameters of a 65 nm standard CMOS process technology, as an example implementation technology.

### DETAILED DESCRIPTION

In the following description, numerous specific details are given to provide a thorough understanding of embodiments. The embodiments can be practiced without one or more of the specific details, or with other methods, components, materials, etc. In other instances, well-known structures, materials, or operations are not shown or described in detail to avoid obscuring aspects of the embodiments.

Reference throughout this specification to “one embodiment” or “an embodiment” means that a particular feature, structure, or characteristic described in connection with the embodiment is included in at least one embodiment. Thus, the appearances of the phrases “in one embodiment” “according to an embodiment” or “in an embodiment” and similar phrases in various places throughout this specification are not necessarily all referring to the same embodiment. Furthermore, the particular features, structures, or characteristics may be combined in any suitable manner in one or more embodiments.

The headings provided herein are for convenience only and do not interpret the scope or meaning of the embodiments.

An AVS voltage can be divided into a process-related constant DC voltage or offset voltage and a temperature-dependent voltage, where, in fact, only the temperature coefficient is important. This insight has led to the here-disclosed concept of the Semi-Adaptive Voltage Scaling (SAVS).

AVS of the prior art generally relies on a closed-loop and critical path model or replica to continuously update the supply voltage to reflect process-related device parameters and possible change of operating conditions. It will be shown in the following that the SAVS concept according to an embodiment uses an open-loop and restricts voltage update only to temperature variation. Moreover, the voltage portion in the supply voltage for the electronic device that reflects process-related parameters, as well as selection of a proper temperature coefficient, may be done only once by performing a test, such as a critical path test for the electronic device in a closed-loop, and by storing these results in a dedicated, and in an embodiment, non-volatile, memory for later use in operation of the electronic device. In an embodiment, each individual electronic device or circuit is processed. In operation, SAVS operates in open-loop, whereby the supply voltage can be established much faster than in closed-loop AVS schemes of the prior art.

Additionally, already mentioned hereinabove, SAVS also allows frequency scaling with energy efficiency as in closed-loop AVS of the prior art. The frequency scaling configuration of the SAVS may be implemented with additional memory for storing of respective information related to the at least one offset voltage and the at least one temperature related parameter at each frequency of the system. It goes without saying, that the SAVS information does not need to be determined for each individual frequency, rather suitable frequency steps or intervals may be used together with any suitable approach for setting SAVS in between the individual points, such as interpolation.

In CMOS integrated circuits, supply voltage has strong impact on propagation delay of logic gates, Flip-Flops, etc., and therefore, on the performance level of embedded processors. Supply voltage scaling is a way of performing required workload, while minimizing energy consumption of a processor. Supply voltage scaling employs basically a control system and this system can either be open-loop, such as DVS, or closed-loop. Basically, scaling of the supply voltage for an electronic circuit, such as digital VLSI circuits, has proven to be a very efficient way to improve the energy efficiency, where either dynamic voltage scaling (DVS) or adaptive voltage scaling (AVS) can be selected. Accordingly, the supply voltage is dynamically changed taking into account variations due to differences in process tolerance of each individual device and ambient temperature. As a result, an electronic circuit receives its tailored supply voltage, which is controlled and adjusted, at any time, to the minimum for the required performance level. However, up to now, supply voltage scaling comprises a complex system with a closed-loop, which required considerable design efforts.

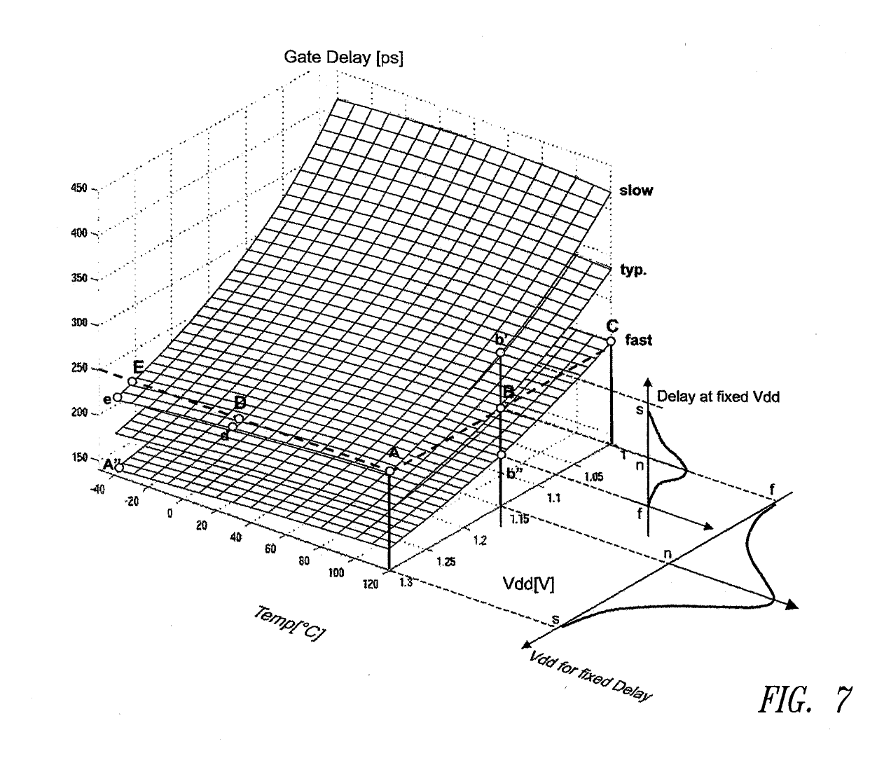

Now with reference to FIG. 7, there is illustrated the gate delay against the supply voltage, the temperature, and process variations, such as slow, nominal, and fast, of 65 nm standard CMOS process technology. It is worth noting that the kind of technology mentioned in connection with the described embodiment serves as a non-limiting example for the implementation of an embodiment. Process variation has strong impact on achievable gate delay. For example, with reference to FIG. 7 at t=+120° C. and a fixed supply voltage of 1.15 V, for example, a delay of 250 ps can be obtained for a typical (nominal) production process (cf. point B in FIG. 7). However, as can be derived from FIG. 7, this delay changes to 310 ps for slow (cf. point b′ in FIG. 7) and 200 ps for fast (cf. point b″ in FIG. 7) processes, respectively. In order to maintain the same delay, the supply voltage for slow process must be increased up to 1.3 V (cf. point A in FIG. 7), whereas for fast process, the supply voltage may be reduced down to 1.0 V (cf. point C in FIG. 7). This is the basic idea of voltage scaling.

In other words, point A in FIG. 7 represents the worst-case of gate delay, i.e., slow and +120° C., which, however, does not coincide with the worst case of energy consumption, which lies at point A″ —A combination of fast process and lowest temperature (−40° C.).

DVS is a lookup table (LUT) based approach as also described in M. Hartman, “PowerWise adaptive voltage scaling minimizes energy consumption,” Information Quarterly, vol. 3, no. 1, pp. 27-29, 2004 (Hartman). Briefly, in DVS, a voltage vs. frequency table is maintained where the predetermined voltages have minimum values, which guarantee functionality over all circuit parts and temperatures. From FIG. 7, it can be seen that for τ≦250 ps over process and temperature variations, the supply voltage must be at least 1.3 V, determined by point A, whereas for τ≦310 ps, the supply voltage may be reduced down to 1.15 V, which is determined by point b′, etc. Consequently, DVS does not yield maximum energy saving because headroom must be included in the pre-characterized voltage to meet timing criteria over all parts and under all operating conditions, and for robustness.

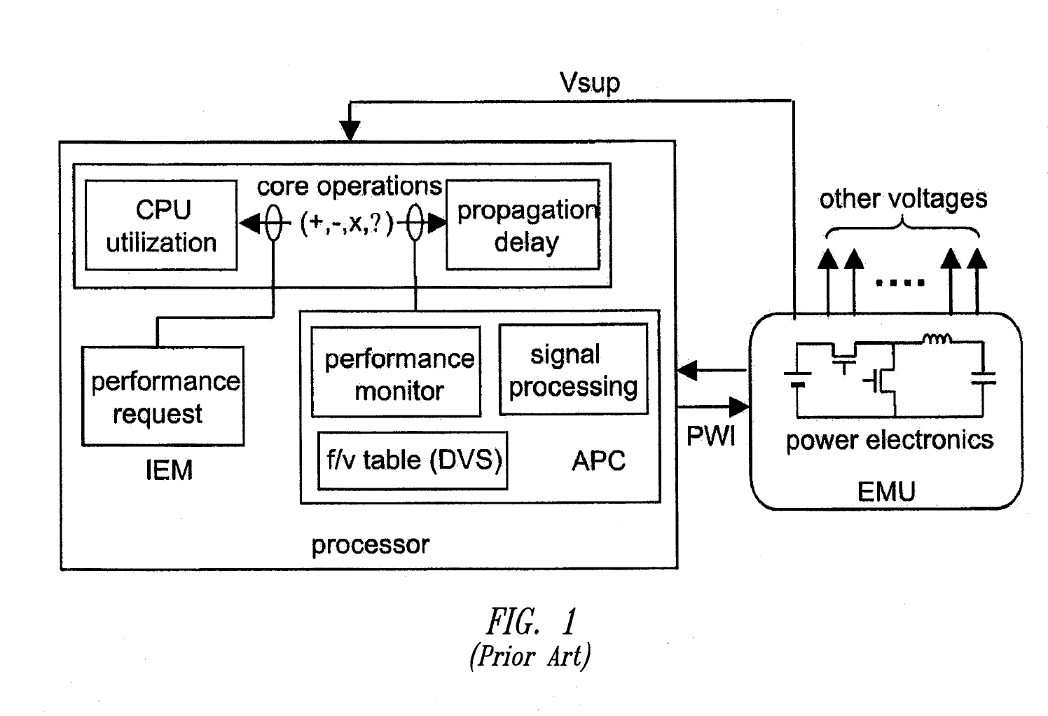

In contrast to DVS, AVS is a closed-loop approach that adjusts supply voltage to the lowest possible level for any given electronic device and various operating conditions to reduce energy consumption. Different from DVS, AVS is more energy efficient and can yield more energy saving at the same performance level. Referring to FIG. 7, for the same delay of 250 ps, supply voltage may be set adaptively to 1.3 V, 1.15 V, and 1.0 V for slow, typical, and fast processes, respectively (points A, B, and C). These voltage levels can be reduced further as temperature decreases. Of course, this has its price. The complexity of an AVS example is schematically illustrated in FIG. 1, which is also taken from above-mentioned Hartman. Briefly, the AVS system comprises two hardware components: an Intelligent Energy Manager (IEM) and an Adaptive Power Controller (APC), both located in the processor of the electronic device, and the AVS compliant Energy Management Unit (EMU).

The SAVS concept according to an embodiment of the present disclosure is in contrast to prior art solutions, an open-loop configuration, is much simpler, has virtually no silicon cost, is easier and quicker to implement, and is capable of yielding at least the same energy saving as the closed-loop AVS of the prior art.

As mentioned above, the idea behind one embodiment of an AVS is to adjust supply voltage, at any time, to the lowest possible voltage for any given device, i.e., regardless of process variations, and over temperature range. In the following, for better illustration, only a single operating frequency is considered, but a multi-frequency application is possible and will be discussed later herein.

The supply voltage under AVS control can be written as equation (1):

Vₛᵤₚ_{_{AVS}}=Vₛᵤₚ_{₀}+ΔV_{proc}+ΔVₜₑₘₚ (1)

where the first term on the right hand side is the lowest supply voltage (minimal supply voltage) under typical conditions, i.e., typical process and t=27° C. ΔV_{proc} and ΔVₜₑₘₚ are the required voltage increments due to process variation and temperature variation, respectively. With typical process values ΔVₚᵣₒₚ=0, and ΔVₜₑₘₚ=0 at t=27° C., equation (1) results to be

Vₛᵤₚ_{_{AVS}}=Vₛᵤₚ_{₀}

Considering that process-related device parameters vary from batch to batch, wafer to wafer, and chip to chip, but are fixed after fabrication and remain unchanged during lifetime, AVS is a real-time control system, where the supply voltage is updated continuously.

It has been recognized that, as process related device parameters do not change, only ΔVₜₑₘₚ really needs to be updated as temperature changes and, moreover, ΔV_{proc} does not require to be updated at all. The perception of this observation forms the basis for the SAVS concept of the present disclosure. Accordingly, equation (1) can be reduced to equation (2):

Vₛᵤₚ_{_{AVS}}=Vₛᵤₚ_{₀}+ΔVₜₑₘₚⱼ (2)

where Vₛᵤₚ_{_{AVS}} is defined as the lowest possible supply (minimum) voltage at a standard temperature, such as t=27° C., for a semiconductor circuit or device j.

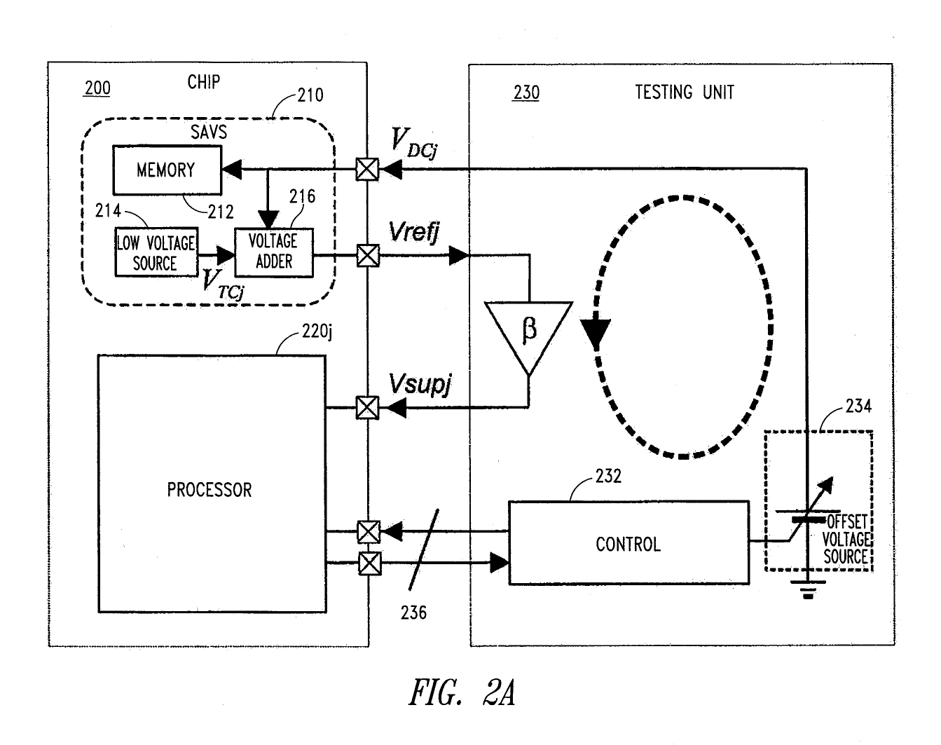

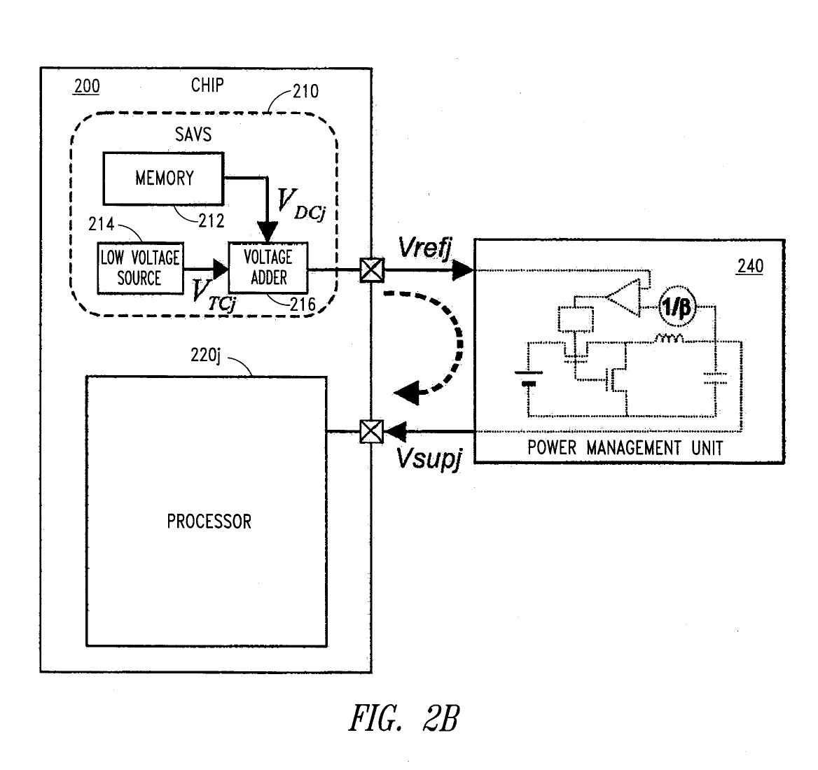

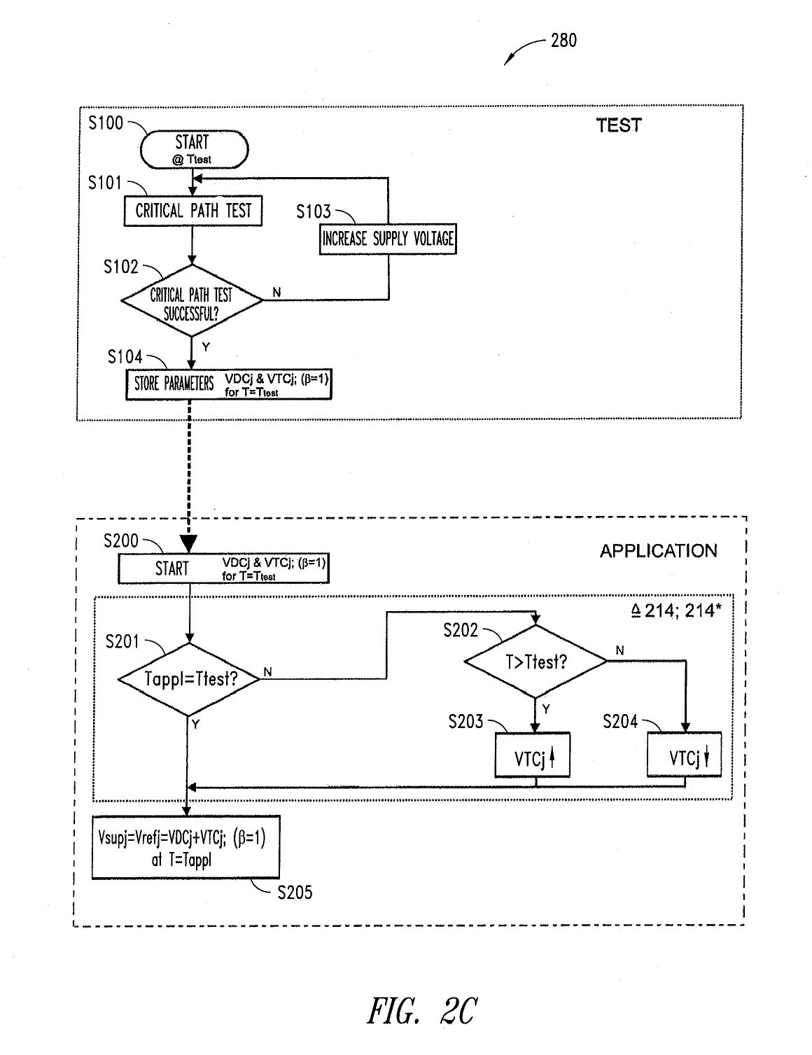

Now with reference to FIGS. 2a and 2b, the general implementation principle of the SAVS concept according to an embodiment will be described. SAVS can, for example, be embedded in an energy-aware design of an electronic device comprising integrated semiconductor circuitry, such as a processor 220j or the like. A SAVS unit 210 or SAVS circuit may be implemented together with the processor 220j on the same chip 200, such that both have the same temperature in application/operation.

As discussed above, the basic idea of SAVS is to set and store information related to the minimum supply voltage at an arbitrary testing temperature, which is preferably a higher temperature than normal operation temperature, but which may, but not necessarily has to, be the maximum temperature.

Therefore, as illustrated in FIG. 2a, during production, the SAVS unit 210 or alternatively a testing unit 230 determines or selects, respectively, a suitable low-voltage source 214 providing a low-voltage (V_{TCj}) with a proper temperature coefficient (TCj) as temperature related parameter for each individual electronic device j, that is for each individual processor 220j.

Then the selected low-voltage (V_{TCj}) is added by suitable means for adding voltages, such as a voltage adder 216 to a DC voltage or offset voltage (V_{DCj}) provided by an offset voltage source 234, which is adjustable by a controller 232, which may comprise, for example, discrete circuitry, one or more processors, one or more memories, or various combinations thereof, of the testing unit 230 to produce a reference voltage (V_{refj}), as expressed by following equation (3).

V_{refj}=V_{DCj}+V_{TCj} (3)

The reference voltage, in turn, is provided to the testing unit 230, which may be implemented in already existing production test equipment. Alternatively, the reference voltage may be provided to a separate power management unit, which generates the required supply voltage in accordance with the reference voltage. In FIG. 2a, the testing unit 230 regenerates the respective supply voltage Vₛᵤₚⱼ(=βV_{refj}) for the processor 220j.

Now, the minimum supply voltage is determined through a critical path test during production test in a closed-loop mode, where control means 232 of the testing unit 230 control the critical path test via a respective control interface 236 to the processor 220j. As mentioned before, the generation of the supply voltage Vₛᵤₚⱼ(=βV_{refj}) from the reference voltage can alternatively be located outside the testing unit, e.g., a suitable power management unit (PMU), as used in an application of the processor 220j.

The values of the determined offset-voltage (V_{DCj}), as well as a selection code for identifying the low-voltage source (V_{TCj}), is then stored in the SAVS unit 210, e.g., into a dedicated memory 212 thereof.

Now with reference to FIG. 2b, in the application, i.e., in operation of the individual electronic device, the SAVS unit 210 is operated in an open-loop mode or configuration. In case that the ambient temperature in application of the processor 220j were the same temperature as during the production test (i.e., the testing temperature), the information identifying the temperature related parameters. (V_{DCj} and V_{TCj}) retrieved from or read out the memory 212 would match to the temperature condition in application, i.e., V_{refj} would resume the same value as once determined during production test, illustrated in FIG. 2a.

As temperature varies in application, V_{TCj} provided by the low-voltage source 214 is automatically adjusted, i.e., self-adjusted as explained later, in such as way that V_{refj} is also adjusted to the respective minimum voltage, i.e., minimized, while the desired performance level of the processor 220j is maintained. To that effect, the self-adjusted voltage V_{refj} can be provided to a power management unit (PMU) 240, which may also be implemented on-chip together with the processor 220j or off-chip, as well. The PMU 240, in turn, supplies the required minimal supply voltage (Vₛᵤₚⱼ(=βV_{refj})) to the processor 220j. In other words, there is neither feedback nor closed-loop in the application.

In contrast to the prior art, where the minimum supply voltage for the processor is determined solely by, for example, an Adaptive Power Controller (APC), and without any involvement of a tester, such as the testing unit 230, SAVS allows the testing unit 230 to play an important role in that process. During the production test, the testing unit 230 behaves not only as a PMU of the prior art. The testing unit 230 closes the control loop (closed-loop mode/configuration), and determines the minimal supply voltage based on the result of a predetermined criterion such as a predetermined test, e.g., one or more critical path tests in which gate delay of the circuit is measured, of the individual electronic device, i.e., the processor 220j in the described embodiment.

Summarizing, in the here proposed SAVS, the testing unit 230 is endowed with playing new and important roles: (1) Closing the control loop when acting as PMU (or at least controlling a respective PMU) during production testing, and (2) Determining as SAVS parameters information on both the voltage V_{DCj} and voltage V_{TCj} by performing a suitable performance test for the device j, such as the critical path tests, for preferably each individual semiconductor circuit or device j during production, wherein the respective test result are delivered to the SAVS unit 210 such that the SAVS parameters, i.e., the information related to at least one offset voltage and at least one temperature related parameter, which identify the minimal supply voltage for the semiconductor circuitry at the testing temperature such that to meet a predetermined test of the semiconductor circuitry, can be stored into a dedicated, preferably non-volatile, memory, for instance, an electronic memory 212 in the SAVS unit 210. However, as already mentioned it is also possible to have an electronically rewriteable memory 212, which allows for a revision or an amendment of the stored SAVS information, if desired.

It is worth noting that although in prior art AVS configurations a tester may also act as a PMU, the supply voltage is determined without any involvement of the tester. This is one major distinction between the prior art and the here-introduced SAVS. As it regards the test criterion, a scan test can be used for testing the critical path, as described for instance in T. Olsson et. al., “Dual supply-voltage scaling for reconfigurable SoCs,” Proc. ISCAS'01, vol. 2, pp. 61-64, 2001.

In the application, i.e., in operation of the processor 220j, the SAVS unit 210 is in open-loop, retrieves the previously during production measured and proven data out of the memory 212, and regenerates voltage V_{refj}, for the individual device, i.e., processor 220j. This special strategy permits SAVS to deliver the correct supply voltage and to offer closed-loop energy efficiency without problems associated with closed-loop such as being prone to instability and having long settling times, as in the prior art solutions.

Now with respect to FIG. 2c and considering FIGS. 2a and 2b, the basic concept of an embodiment of a method 280 of the herein disclosed SAVS concept is illustrated by way of a flow chart, where in the top portion the steps taken during production are illustrated, in which the parameters for SAVS for an, preferably each individual, electronic circuit or device during production are determined. These steps are performed in the closed-loop configuration/mode as shown in FIG. 2a. The determined SAVS information or parameters can later be used in an application, i.e., in operation of the electronic circuit or device. In operation, the respective self-adjusting process of the SAVS concept is performed, of which an embodiment is illustrated for better illustration in an abstract approach also by way of a flow chart in the bottom portion of FIG. 2c. It will be appreciated that the flow-chart for the self-adjusting operation is not necessarily reflecting software steps performed by a programmable hardware or hardware realized software steps, rather the steps of the flow chart are intended for better understanding of the operation principle and may typically be implemented, for example, using discrete hardware components.

Accordingly, in the production part (a) of SAVS, illustrated in the top portion of FIG. 2c, an electronic device is connected with a respective SAVS testing unit and the production test is started (S100) at an actual test temperature (T_{TEST}), which preferably is a higher temperature as a normal application temperature for the electronic device in application, but needs not to be the highest temperature for which the electronic device is specified. In accordance with the actual test temperature, a low-voltage source (V_{TCj}) with a proper temperature coefficient (TC; αᵢ) is set to which a first offset voltage (V_{DCj}) is added for producing a first reference voltage (V_{refj}). Based on the reference voltage the testing unit generates a corresponding supply voltage (Vₛᵤₚⱼ) which is supplied to the electronic device for testing.

In step S101, a critical path test is performed for the electronic device for checking whether performance requirements, e.g., delays, can be met by the electronic device, if supplied with the actual supply voltage (Vₛᵤₚⱼ) supplied by the testing unit.

In step S102 it is determined whether the critical path test has been passed successfully or not. In the case NO (N) then the process continuous with step S103, in which the supply voltage is increased by means of selection of another temperature coefficient (TC; αᵢ) in connection with a respective adjustment of the offset voltage (V_{DCj}). Then the process goes back to step S101 and S102, i.e., the critical path test is repeated.

Once in step S102 it is determined that the critical path test requirements are met, e.g., required delay of the critical path is met, the process continuous to step S104. Hence, the required information related to at least one offset voltage (V_{DCj}) and at least one temperature related parameter (TC; αᵢ), which identify the minimal supply voltage for the semiconductor circuitry at the testing temperature such that to meet a predetermined test of the semiconductor circuitry, have been determined as the SAVS parameters.

In step S104, the determined SAVS parameter values for the low-voltage source (V_{TCj}) with the proper temperature coefficient (TC; αᵢ) and the respective adjusted offset voltage (V_{DCj}) are stored into dedicated memory 212 of the SAVS unit 210, which preferably is located together with the electronic device on-chip, e.g., as a System-on-Chip (SoC). However, also an off chip solution, depending on the application requirements of the electronic device or other restrictions is possible.

In the application part (b) of SAVS illustrated in the bottom portion of FIG. 2c, i.e., during operation of the electronic device, the SAVS procedure starts at step S200, in which the stored (device individual) SAVS parameter values are retrieved/read from the memory of the SAVS unit, i.e., the stored information, i.e., SAVS parameter values for identifying or selecting the low-voltage source (V_{TCj}) with a proper temperature coefficient (TC; αᵢ) as well as for setting the respective adjusted offset voltage (V_{DCj}), which have been determined during production testing as described above.

As mentioned above, in the following the operation of the SAVS unit is explained by way of a flow chart in an abstract manner using process steps. However, it is apparent that due to the nature of implementation these steps are not necessarily performed in the manner of a computer program, rather the basic working principle is explained and typically may be implemented using discrete components.

In step S201, the SAVS unit 210 implicitly checks whether the actual temperature (T) of the electronic device is equal to the test temperature (T_{TEST}) during production testing. In case, that the actual temperature (T) is not equal (N) to the previous test temperature (T_{TEST}) the SAVS procedure goes to step S202.

In step S202, it is basically checked whether the actual temperature (T) is higher or lower as the previous test temperature (T_{TEST}). In the embodiment illustrated in FIG. 2c, in step S202 it is checked whether the actual temperature (T) is higher as the previous test temperature (T_{TEST}). If the outcome of the test is YES (Y) the SAVS procedure goes to step S203, otherwise (N) it goes to step S204, respectively for adjusting of the low-voltage source (V_{TCj}).

In step S203, the set low-voltage source (V_{TCj}) will be increased, whilst in step S204 the low-voltage source (V_{TCj}) will be decreased, respectively in accordance with the actual deviation between the production test temperature (T_{TEST}) and the actual temperature (T). Then the SAVS procedure goes to step S205.

In step S205, the reference voltage (V_{refj}) based on the adjusted low-voltage source (V_{TCj}) and the offset voltage (V_{DCj}) is supplied to, for example, a respective power management unit (PMU) of the electronic device, which generates the required supply voltage for the electronic device according to Vₛᵤₚⱼ=βV_{refj}; for sake of simplification, in step S205 of FIG. 2c it is assumed that β=1, accordingly Vₛᵤₚⱼ becomes V_{refj}.

Compared to prior art solutions, an embodiment does not need a delay monitor, instead the real delay of each individual electronic device, e.g., the processor 220j in FIGS. 2a to 2c, is measured at least once, preferably during production test, alternatively or additionally during packaging of the electronic semiconductor circuit, and alternatively or additionally in application of the electronic semiconductor circuit, if the SAVS memory may be rewritable. Further, advantageously the production test can be done at any temperature. Furthermore, there is no need for a start-up calibration procedure to be executed after power-up of the electronic device. Moreover, there is no need for periodic temperature measurements in order to track temperature variation, rather a compensation for the effect of the temperature is performed continuously by means of the low-voltage source (T_{TCj}) with its proper temperature coefficient (TC; αᵢ) generator. Thus, the supply voltage can be continuously, not periodically, adjusted. Hence, in devices implementing embodiments of the SAVS of the present disclosure operation of the electronic device can be started immediately after power up, in particular, periodical updating is not required.

In contrast, in prior art AVS systems, there is no difference between production test and application of the electronic device, at all. If it is assumed that a certain electronic device is OK, there is normally no test needed and also not made. That is, the device is put directly into application. In contrast thereto, in the SAVS concept according to an embodiment by way of a production test, process information is acquired to determine the process-related supply voltage portion and the temperature-related portion. It is worth highlighting that this may be done only at a single arbitrary temperature at which the test is performed. In other words, there is no need to determine a certain test temperature, which has to be maintained and controlled for the test, at all.

Further, in application of the electronic device, SAVS is in open-loop configuration because (1) there is no need for a closed-loop configuration and (2) there is no tester-like unit in application, i.e., it is not required, hence no requirement for replacement, either. As a result, in an embodiment SAVS is a semi-adaptive approach, which is the basic idea of SAVS.

In the following, it will be demonstrated that like prior art AVS, in an embodiment SAVS is able not only to recover many voltage margins added by dynamic voltage scaling (DVS) but also to reduce some of them further.

A first aspect is process variation, it has been found that gate delay and path delay depend strongly on the process and among all voltage margins the one related to process variation is probably the largest added to open-loop DVS supply voltage. Because the DC or offset voltage (V_{DCj}) can be set individually for each semiconductor circuit or device by measuring the critical path delay, SAVS is able to recover this voltage margin completely.

A second aspect is temperature variation, every electronic device experiences temperature variation, in particular gate delay is influenced by temperature. In this connection, it has been found that the same gate delay can be maintained by a simple, first-order supply voltage adaptation, which allows for reducing a great deal of voltage margin in association with temperature variation, while lowering adaptively the supply voltage; also energy consumption is lowered. The voltage margin can be reduced further if a more sophisticated curvature supply voltage adaptation vs. temperature is provided.

A third aspect is voltage-drop (IR-drop), it has been found that in association with IR-drop the voltage margin is absolutely minimum for the SAVS according to an embodiment thanks to direct measurement of the critical path electrical device, e.g., the processor 220j of FIGS. 2a, 2b. By contrast, for prior art AVS, this would require exactly the same voltage drop along the power grid of the APC, and along the power grid of the cells where the critical path of the processor is located. As IR-drop is a product of current and parasitic resistance of metal wires, trying to maintain equal IR-drops for both is difficult.

A forth aspect is regulator tolerance, it has been found that with SAVS according to an embodiment, voltage margin in association with regulator tolerance is completely removed from the supply voltage of the electronic device, such as the processor 220j in FIGS. 2a, 2b, if the regulator is located on-chip.

A fifth aspect is delay mismatch, it has been found that voltage margin can be included in the modeling of the delay of the critical path as well as in the implementation of the delay lines for AVS. For example, in N. Dragon et. al., “An adaptive on-chip voltage regulation technique for low-power applications,” Proc. ISLPED'00, pp. 20-24, 2000, 10% up to 15% delay margin was added to the critical path replica, which is translated to a voltage margin. As matter of fact, due to process imperfections, component mismatch is unavoidable. That is, the critical path delay is affected by many factors including supply voltage, process and temperature, interconnect parasitics, load, etc. However, SAVS according to an embodiment is able to eliminate this voltage margin completely and to deliver a minimum supply voltage thanks to direct measurement of the critical path. For robust operation, however, a reasonable safety margin may be added.

In a further development of the SAVS according to an embodiment, also frequency scaling is used, since the discussion above is equally valid for other operating frequencies of the electronic device. In other words, for the purpose of frequency scaling, basically, only the memory capacity of the SAVS unit needs to be adapted accordingly.

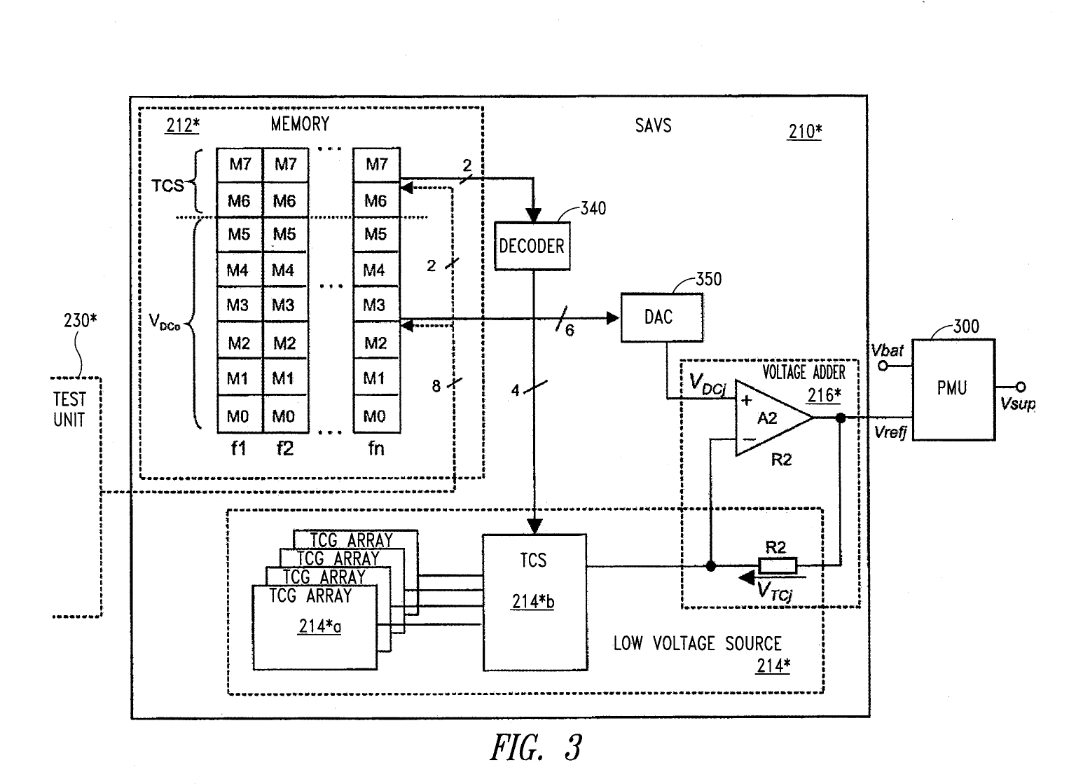

With respect to FIGS. 3 to 6, by the way of an example, details of embodiments of SAVS devices and systems will be disclosed for better illustration. However, it is understood that the SAVS concepts are not to be restricted to the following embodiments of certain implementation details thereof.

In the following, FIG. 3 shows a more detailed block diagram of a SAVS unit 210 of an embodiment which allows for combined frequency and voltage scaling. It is understood that the SAVS unit 210 may also be used without frequency scaling depending on the application requirements.

In FIG. 3, an embodiment for a SAVS unit 210* comprises an n×8 bit memory 212*, the low-voltage source 214* providing a low-voltage (V_{TCj}) with a proper temperature coefficient (TCⱼ) comprised of a temperature coefficient generators (TCGs) array 214*a together with a temperature coefficient (TC) selection (TCS) unit 214*b, which is controlled by a 2-to-4-decoder 340, a 6 bit-digital-to-analog-converter (6 bit-DAC) 350, and the voltage adder 216* with inherent buffering/driving capability. On the left hand side of FIG. 3, the connection to the testing unit 230 during production testing is depicted, whilst on the right hand side of FIG. 3 a power management unit (PMU) 300 is depicted which is configured to provide the required supply voltage (Vₛᵤₚⱼ) for the device j in accordance with the reference voltage (Vₛᵤₚⱼ).

In the following, one respective implementation of an embodiment of these circuit blocks will be described.

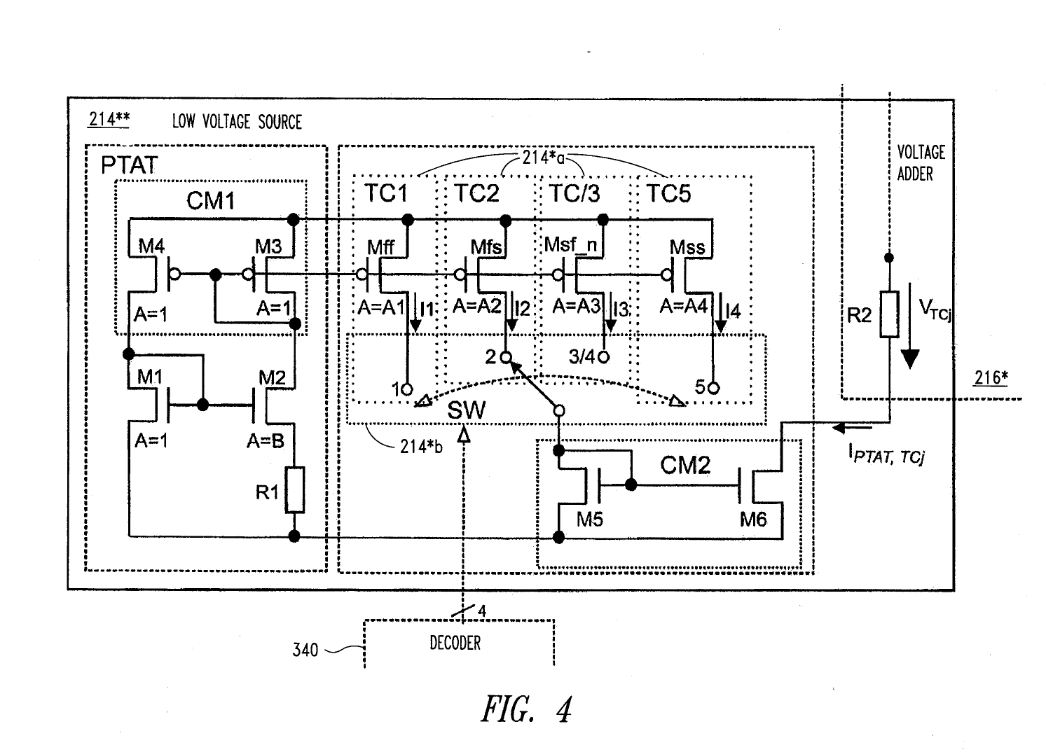

Now with respect to FIG. 4, a possible hardware implementation of a low-voltage source 214** comprising the TCGs array 214*a and the unit 214*b of FIG. 3 is described. As one simple embodiment of a circuit capable of outputting a constant and positive TC signal a current generator providing a current proportional to the absolute temperature. In FIG. 4 an implementation with a circuit depicted with reference sign PTAT, wherein “PTAT” stands for “Proportional-To-Absolute-Temperature”. Basically in the PTAT section 414, by forcing MOS transistors to operate in weak inversion, a PTAT current generator is realized in CMOS.

FIG. 4 shows a complete implementation of a low-voltage source 214** with the TCGs array 214*a together with the temperature coefficient (TC) selection unit 214*b of FIG. 3. The low-voltage source 214** of FIG. 4 is capable of providing five different and selectable temperature coefficients TCs, as a temperature related parameter. It is noted that by the shown principle a low-voltage source with any required or suitable number of selectable temperature coefficients TCs can be implemented.

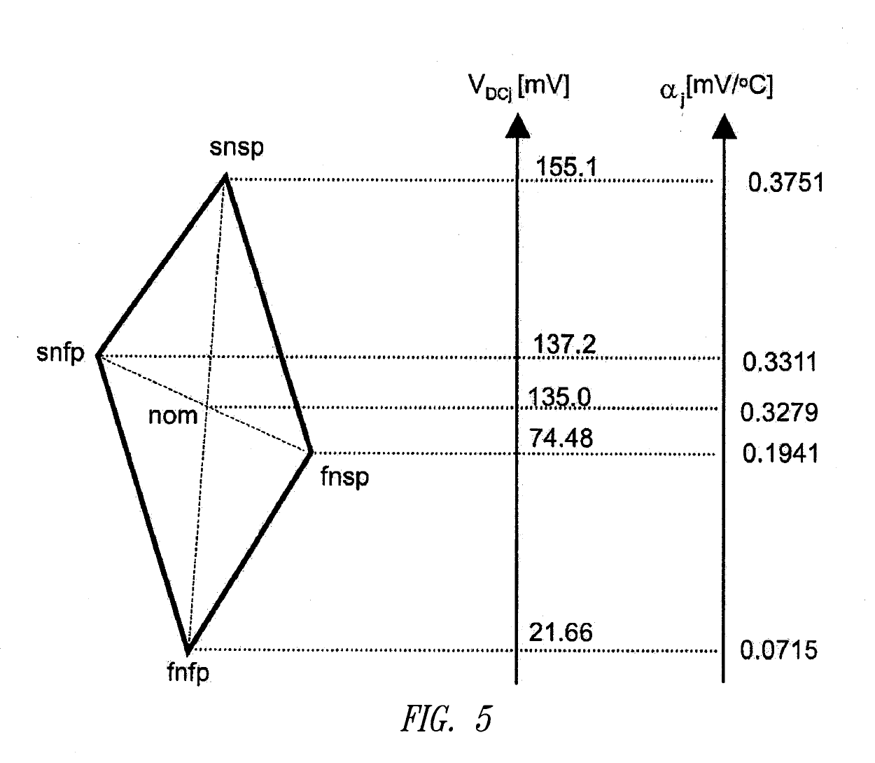

In the PTAT section, the transistors M1 and M2 operate in weak inversion while the remaining transistors are in saturation region. Transistors M3 and M4, as well as M5 and M6, form two current mirrors CM1 and CM2 with unity current ratio. Accordingly, a temperature coefficient TC can be selected via provided switches 1, 2, 3/4, and 5, which are illustrated in a simplified manner and can be realized e.g., by respective MOS switching transistors. Thus, the four transistors Mff, Mfs, Msf_n, and Mss, are each selectable via a respective switch 1, 2, 3/4 and 5, have different sizes (indicated by the aspect ratios A1, A2, A3, A4) which correspond to the five different temperature coefficients TCs in association with four process corners plus nominal (typical) process as defined in the following Table 1 and illustrated in FIG. 5.

TABLE 1
DEFINITION OF PROCESS CORNERS
AND NOMINAL PROCESS

| | PMOS | NMOS |
|---|---|---|
| snsp | V_{Tmax}, βₘᵢₙ | V_{Tmax}, βₘᵢₙ |
| snfp | V_{Tmin}, βₘₐₓ | V_{Tmax}, βₘᵢₙ |
| nom. | V_{T}, β | V_{T}, β |
| fnsp | V_{Tmax}, βₘᵢₙ | V_{Tmin}, βₘₐₓ |
| fnfp | V_{Tmin}, βₘₐₓ | V_{Tmin}, βₘₐₓ |

For i-th TCG, the output voltage can be expressed according to equation (5):

V_{TCi}(t)=V_{DCi}+αᵢ(t−tₘₐₓ₎ (5)

where V_{DCi} is the output voltage at highest temperature, tₘₐₓ, and αᵢ is the respective temperature coefficient TCi.

With the implementation embodiment shown in FIG. 4, V_{DCi} is a constant but varies with i. It is worth to be noted that the actual value, more precisely the absolute value, of V_{DCi} is not important because it is much smaller than V_{refj}, and any deviation due to tolerance will be compensated. The value of αᵢ is chosen in such a way that over the entire temperature range maximum energy saving is achieved.

With the circuit of FIG. 4, it can also be demonstrated by equations (6):

$${V}_{DCi} = \frac{( 273 + {t}_{max} ) \cdot {A}_{i} \cdot K \cdot R 2}{qR 1} ln B \\ {α}_{i} = \frac{{A}_{i} \cdot K \cdot R 2 \cdot t}{qR 1} ln B \qquad ( 6 )$$

where Aᵢ is the aspect ratio of the transistor selected by a respective switch 1, 2, 3/4, and 5 in position i to transistor M3. It is noted that both V_{DCi} and αᵢ depend on several design parameters such as R1, R2, Aᵢ, and B, which offer same dimension of design freedom. In this design, it has been chosen R1=R2 and B to be fixed.

Different TCs can then be obtained by changing Aᵢ, respectively. It was found in the design that a single transistor M_{sf}_{_{—}}ₙ can offer the required TCs for both nominal and process corner snfp. Accordingly, circuits with nominal process and each of these four process corners can be simulated. FIG. 5 shows the simulated V_{DCi} and αᵢ for the process corners as defined in the table 1 above.

Accordingly, by the circuit illustrated in connection with FIG. 4, a low-voltage source 214** is proposed for providing a temperature related voltage V_{TCj} having a selectable temperature coefficient TC1, TC2, TC3/4, and TC5.

The low-voltage source 214** of FIG. 4 comprises the current source section PTAT for generating a temperature related current which is proportional to the absolute temperature. In the current source section PTAT a first transistor M1 and a second transistor M2 are configured to operate in weak inversion are each respectively connected to a third transistor M3 and a fourth transistor M4 of a first current mirror CM1, which are configured to operate in saturation region.

The second current minor CM2 is comprised of a fifth transistor M5 and sixth transistor M6. The second current mirror CM2 is selectable coupleable via one of a group of coupling transistors Mff, Mfs, Msf_n, and Mss to first current mirror CM1 of the current source section PTAT. The coupling transistors Mff, Mfs, Msf_n, and Mss are configured to provide in accordance with the temperature related current of the current source section PTAT a temperature related current with a predetermined temperature coefficient TC1, TC2, TC3/4, and TC5.

For enabling an external selection of a suitable temperature coefficient TC1, TC2, TC3/4, and TC5, there are switching means SW, which are configured for connecting one of the group of coupling transistors Mff, Mfs, Msf_n, and Mss in accordance with an external selection signal to the input current path of the second current mirror (CM2).

Finally, by means of a predetermined output resistor means, e.g., the ohmic resistor R2, connected to the output current path of the second current mirror CM2 the temperature related voltage V_{TCj} is provided as voltage drop over the output resistor R2.

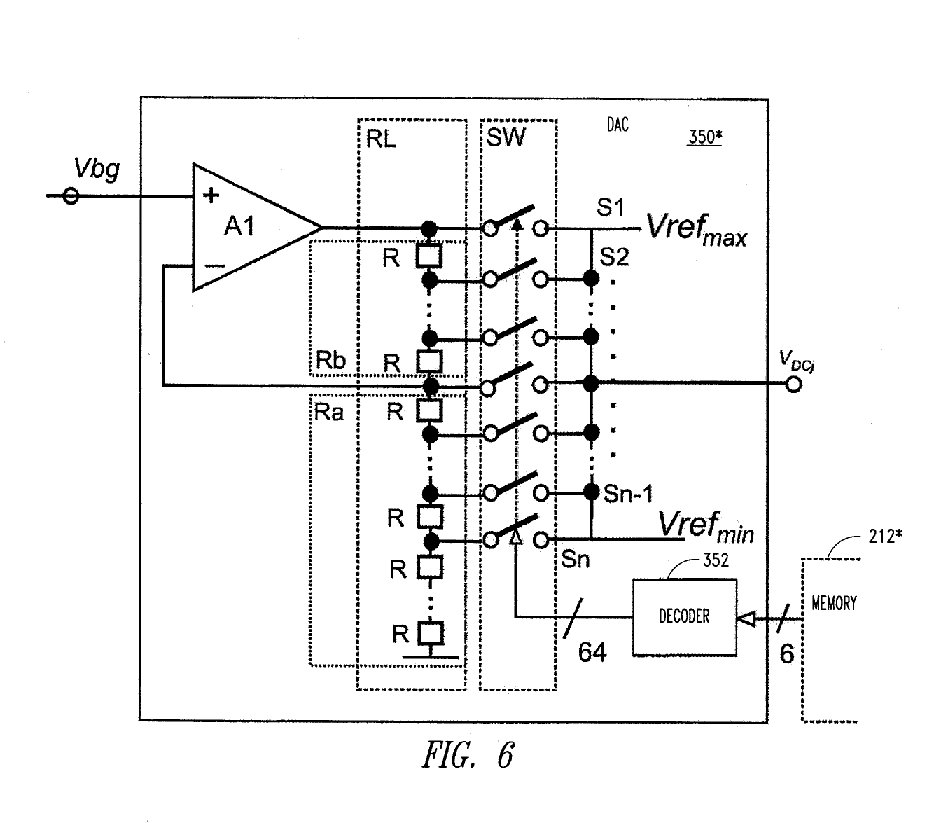

Now with reference to FIG. 6, an embodiment 350* of the DAC 350 in FIG. 3 is shown. In the design of the embodiment, the supply voltage range is assumed to be between 1.0 V to 1.3 V. The higher limit of the supply voltage range is set by the process technology, whereas the lower limit is set by the system. In order to use resources efficiently, the DAC 350 may not need to cover ranges beyond that. A 6 bit-DAC is able to cover this range with a resolution of 4.6875 mV. By comparison, for the same resolution, an 11 bit-DAC would be needed to cover the entire range from 0V to 1.3V with the same resolution.

For sake of simplicity, it is assumed that β=1 as in FIGS. 2a and 2b, so that Vₛᵤₚ becomes V_{ref}. The maximum voltage of V_{ref} will be 1.3 V. Accordingly, a conventional design would generate this voltage by amplifying a precision reference voltage such as band-gap-circuit, which is typically 1.2 V, by a gain of 1.3/1.2. This would require an operational amplifier and two resistors. Then a resistor ladder DAC, for example, would follow the gain stage. The upper terminal of the ladder would be connected to the output of the preceding gain stage. As an alternative implementation, digital-to-analog conversion can be first performed with the full swing level of 1.2V followed by a gain stage.

In the here proposed embodiment of the DAC 350* shown in FIG. 6, the gain stage and the resistor ladder are merged. Further, the resistor ladder RL is simultaneously used to determine the DC gain of the operational amplifier A1 by means of the respective switches S1 to Sn, which are configured to be controlled by a 6-to-64 decoder 352.

Accordingly, the adjustable voltage source 350* is proposed of the kind of a digital-to-analog converter, which comprises a gain stage interconnected with a resistor ladder RL, which is used as resolution step generating unit for the output voltage of the voltage source 350*.

The operational amplifier A1 is connected with the resistor ladder RL, which is basically a series connection of a determined number of resistors R. The resistor ladder RL is connected at a first end with an output of the operational amplifier A1 and a second end to a determined voltage point, e.g., ground, and with one of the interconnection points of the resistor ladder RL to an inverting input of operational amplifier (A1) such as to form a non-inverting configuration of the amplifying unit (A1). Hence, the DC gain of the circuit is well defined in accordance with the well-known relation of the voltage divider formed by the two resistors Ra and Rb of the resistor ladder RL. Accordingly the DC voltage gain corresponds to (Ra+Rb)/Ra.

The resistor ladder RL further provides the adjustable output voltage in respective voltage steps generated by the individual resistors R of the resistor ladder RL. By respective switching means, e.g., MOS transistors switchable in accordance with an external control signal, a selectable connection of one of the interconnection points of the resistor ladder RL with the output of the adjustable voltage source 350* can be established.

As a result, in the adjustable voltage source simultaneously a DC gain of the operational amplifier A1 is set by means of the resistor ladder RL and the output voltage of the operational amplifier A1 is subdivided in respective steps at the resistor ladder RL to provide the adjustable output voltage.

As a result, the resistor ladder in prior art circuits is effectively eliminated, which reduces the energy consumption of the circuit. Hence, the silicon size can also be reduced.

Here V_{ref}_{ₘᵢₙ}=1.0 V and V_{ref}_{_{max n}}=1.3 V as mentioned above.

According to equation (3) above, the SAVS unit performs an addition of two voltages, namely V_{DCj} and V_{TCj}. Considering that both voltages V_{DCj} and V_{TCj} are positive referenced to ground, the sum must also be positive. According to one implementation, in FIG. 3 the addition of V_{DCj} and V_{TCj} is accomplished by applying V_{DCj} directly to the non-inverting input of operational amplifier (op-amp) A2, and by placing, i.e., connecting, resistor R2 in FIG. 4 over the inverting input and the output of the op-amp A2. With this arrangement of the voltage adder 216*, the voltage V_{TCj} which is generated over R2 by a selected output current from the low-voltage source 214*, is added to V_{DCj} so that the sum appears at the output of the op-amp A2 in FIG. 3. Advantageously, there is a buffering property, allowing for driving of heavy loads directly.

Accordingly, in FIG. 3 a simple voltage adder 216* for adding a first and a second input voltage and providing buffering and/or driving capability is shown. The amplifying section, i.e., the operational amplifier A2, has an inverting input and a non-inverting input, which have each a high input impedance, i.e., substantially no current sinks in one of these inputs, when an input voltage is applied. Further, the amplifying section has an output for outputting an output voltage. A determined feedback resistor, i.e., the resistor R2 is connected to the inverting input and the output of the operational amplifier A2.

When a first input voltage, e.g., the offset voltage V_{DCj}, is applied to the non-inverting input of operational amplifier A2, and a second input voltage, e.g., the temperature related voltage V_{TCj} is generated as voltage drop over the feedback resistor R2 by a respective current I_{PTAT}, T_{Cj}, the sum of the first input voltage (V_{DCj}) and second input voltage (V_{TCj}) appears at the output of the operational amplifier (A2).

According to the embodiment, instead of V_{refj}, information related to a pair of V_{DCj} and V_{TCj} is respectively stored in the dedicated memory, e.g., memory 212 of FIGS. 2a and 2b or memory 212* of FIG. 3. These voltage and temperature related values or parameters are determined during production test, for the individual device 220j according to FIGS. 2a and 2b. As a result, device-specific or circuit-specific information for SAVS are stored in the right place in order to assure that at the same temperature the supply voltage of every part is essentially the minimum supply voltage determined once during production test. In the design of the embodiment, an 8 bit memory has been found to be adequate for each frequency f1, f2, . . . fn. That is to say, in FIG. 3 actually a multi-frequency SAVS is shown.

In FIG. 3, the lower 6 bits of the memory 212* are allocated to the DAC 350 for identifying the determined offset voltage V_{CDj}, while the most significant bit (MSB) and second most significant bit (MSB-1) are reserved for the selection of a proper temperature coefficient TC in or from the TCGs block 214*a in the low-voltage source 214*.

Although TC selection can be made automatically by hardware, during, for example, wafer hot test, it is believed that offering a re-check and/or a re-selection possibility during package test at room temperature, or even any time later in application if necessary, can be a plus and provide additional freedom, application flexibility, enhanced robustness, and help to yield maximum energy reduction.

For frequency scaling with a total of, for instance, n clock frequencies f1, f2, fn, the memory 212* in FIG. 3 is, for example, a n×8 bit non-volatile memory such as EEPROM or the like, to enable storage of the n sets of information corresponding to the respective offset voltage values V_{DCj} and respective low-voltage source with a suitable temperature coefficient TC (V_{TCj}).

It is noted that a respective control circuitry is extremely simple, since only two decoders are needed: One is the 2-to-4 decoder 340 of FIG. 3 for selection of an appropriate TC from the TCGs, and the other is the 6-to-64 decoder 352 inside the DAC 350* as shown in FIG. 6.

Summarizing, the concept of a new semi-AVS (SAVS) has been disclosed. The SAVS concept is suitable for systems, devices and methods for determining minimal supply voltages for digital electronic semiconductor circuitry, e.g., microprocessors, of electronic devices underproduction testing and “real” operating conditions. The new SAVS operates in a closed-loop during a production test phase of the circuitry and in an open-loop mode in an application (operation) phase of the semiconductor circuitry. During production testing, a lowermost level of the supply voltage for the semiconductor circuitry is determined at one single defined temperature at which operating specifications of the circuit are met. The lowermost level is stored in a dedicated electronic memory of the circuitry together with temperature dependent parameters. Afterwards, when the digital electronic circuitry is operated in a “real” application, e.g., a mobile phone, the device and method reads the previously measured and proven data out from the electronic memory and regenerates the minimum level of supply voltage for the circuitry, taking into account the actual temperature of the application. As a result, the digital semiconductor circuitry in the “real” application is supplied with a minimum level of supply voltage, whereby the specified parameters of the circuitry are fully met. Thus, a power consumption of the circuitry is advantageously reduced to a necessary minimum.

In contrast to most prior art AVS, the new SAVS is an open-loop system in application and capable of achieving at least the same energy saving as a conventional AVS. Further, frequency scaling is possible with energy efficiency as with a closed-loop AVS. However, neither a critical path model nor a replica is required as the device's critical path is measured during production test, in a closed-loop, wherein the measurement results are stored in the device, e.g., in a dedicated on-chip memory, for later use in the application. It should be appreciated that SAVS is extremely simple, easy, and quick to implement, and does not require any pre-characterization. Moreover, SAVS is very reliable, robust and low risk, and there is virtually no silicon cost. Simulations have shown that up to 65″% energy reduction can be achieved with SAVS.

It will be appreciated that the herein disclosed SAVS concept is a very different implementation vis-á-vis prior art solution based on new findings, namely that an update of AVS supply voltage is only needed due to temperature variation because the process-dependent voltage portion does not change after it once has been determined. This is why it is named semi-adaptive, and the supply voltage is simplified from equation (1) to equation (2), above.

As a result, by SAVS according to the above disclosure, a technical breakthrough can be achieved for low power or low energy oriented semiconductor circuits design such as CMOS digital VLSI design alike SoCs. The most impeccable features are unbelievable simplicity, open-loop control, ultra-low cost, extremely easy and non-risk implementation, last but not least, more energy saving. By SAVS also frequency scaling with closed-loop AVS energy efficiency will be possible. Hence, SAVS is capable of reducing voltage margins to a minimum and thus maximizing battery life by means of very simple efforts from a circuitry point of view. In particular, the field of application of the herein disclosed SAYS concept includes all digital VLSIs in general, including mobile or portable devices with restricted power resources. Such devices include, for instance, digital signal processor (DSP), microprocessor (μP), System on Chip (SoC), and so on, which are intended for mobile or portable electronic devices such as cellular phones, cordless phones, portable navigation systems such as GPS devices, personal digital assistants (PDAs), digital cameras, or any combination of such devices.

While the disclosure has been illustrated and described in detail in the drawings and foregoing description, such illustration and description are to be considered illustrative or exemplary and not restrictive; the disclosure is not limited to the disclosed embodiments. Other variations to the disclosed embodiments can be understood and effected by those skilled in the art in practicing SAVS from a study of the drawings, the disclosure, and the appended claims.

In the claims, the word “comprising” does not exclude other elements or steps, and the indefinite article “a” or “an” does not exclude a plurality. A single element or other unit may fulfill the functions of several items recited in the claims. The mere fact that certain measures are recited in mutually different dependent claims does not indicate that a combination of these measured cannot be used to advantage. Any reference signs in the claims should not be construed as limiting the scope.

The foregoing detailed description has set forth various embodiments of the devices and/or processes via the use of block diagrams and examples. Insofar as such block diagrams and examples contain one or more functions and/or operations, it will be understood by those skilled in the art that each function and/or operation within such block diagrams, flowcharts, or examples can be implemented, individually and/or collectively, by a wide range of hardware, software, firmware, or virtually any combination thereof. In one embodiment, the present subject matter may be implemented via Application Specific Integrated Circuits (ASICs). In one embodiment, the present subject matter may be implemented via one or more digital signal processors executing, for example, instructions stored on one or more memories. However, those skilled in the art will recognize that the embodiments disclosed herein, in whole or in part, can be equivalently implemented in standard integrated circuits, as one or more computer programs executed by one or more computers (e.g., as one or more programs running on one or more computer systems), as one or more programs executed by on one or more controllers (e.g., microcontrollers) as one or more programs executed by one or more processors (e.g., microprocessors), as firmware, using discrete circuitry, or as virtually any combination thereof, and that designing the circuitry and/or writing the code for the software and or firmware would be well within the skill of one of ordinary skill in the art in light of the teachings of this disclosure.

When logic is implemented as software and stored in memory, logic or information can be stored on any computer-readable medium for use by or in connection with any processor-related system or method. In the context of this disclosure, a memory is a computer-readable medium that is an electronic, magnetic, optical, or other physical device or means that contains or stores a computer and/or processor program. Logic and/or the information can be embodied in any computer-readable medium for use by or in connection with an instruction execution system, apparatus, or device, such as a computer-based system, processor-containing system, or other system that can fetch the instructions from the instruction execution system, apparatus, or device and execute the instructions associated with logic and/or information.

In the context of this specification, a “computer-readable medium” can be any element that can store the program associated with logic and/or information for use by or in connection with the instruction execution system, apparatus, and/or device. The computer-readable medium can be, for example, but is not limited to, an electronic, magnetic, optical, electromagnetic, infrared, or semiconductor system, apparatus or device. More specific examples (a non-exhaustive list) of the computer readable medium would include the following: a portable computer diskette (magnetic, compact flash card, secure digital, or the like), a random access memory (RAM), a read-only memory (ROM), an erasable programmable read-only memory (EPROM, EEPROM, or Flash memory), a portable compact disc read-only memory (CDROM), digital tape. Note that the computer-readable medium could be any suitable medium upon which the program associated with logic and/or information can be electronically captured, via for instance optical scanning, then compiled, interpreted or otherwise processed in a suitable manner if necessary, and then stored in memory.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, application and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic device, comprising:
a memory configured to store information related to at least one offset voltage and at least one temperature-related parameter, which identify a minimal supply voltage for a semiconductor circuit at a testing temperature in a closed-loop configuration that satisfies test conditions; and
a reference voltage generator configured to generate a reference voltage corresponding to a supply voltage at an actual operating temperature based on the stored information and the actual operating temperature.

2. The electronic device according to claim 1, further comprising:
a low-voltage source with a temperature coefficient corresponding to the at least one temperature related parameter, and configured to provide a temperature proportional low-voltage.

3. The electronic device according to claim 2 wherein the low-voltage source comprises a current source providing a temperature-related current, which is proportional to an absolute temperature.

4. The electronic device of claim 2 wherein the low-voltage source comprises:
a current source section configured to generate a first temperature-related current which is proportional to an absolute temperature, having a first transistor and a second transistor configured to operate in weak inversion and connected to a third transistor and a fourth transistor of a first current mirror, the third and fourth transistors configured to operate in a saturation region;
a second current mirror having a fifth transistor and sixth transistor, wherein the second current mirror is selectable coupleable via one of a group of coupling transistors to the first current mirror of the current source section and the coupling transistors are configured to provide a second temperature-related current based on the first temperature-related current, the second temperature-related current having one of a set of different temperature coefficients;
a switch configured to connect one of the group of coupling transistors to an input current path of the second current mirror based on a selection signal; and
an output resistor coupled to an output current path of the second current mirror such that a temperature related voltage is provided as voltage drop across the output resistor.

5. The electronic device of claim 4, wherein the first and second current mirrors are configured to have a unity current ratio.

6. The electronic device of claim 4 wherein the switch comprises respective switching transistors coupled to the coupling transistors, and wherein the coupling transistors have different aspect ratios for implementing the set of different temperature coefficients.

7. The electronic device according to claim 3 wherein the low-voltage source further comprises a selector configured to select a respective temperature coefficient based on the temperature-related current provided by the current source.

8. The electronic device according to claim 7 wherein the selector comprises selectable switches configured to select one of several determined temperature coefficients based on the at least one temperature-related parameter.

9. The electronic device according to claim 8, further comprising a converter configured to convert the temperature-related current provided by the current source into a respective temperature-related voltage.

10. The electronic device according to claim 1, further comprising:
an adjustable voltage source configured to provide the at least one offset-voltage.

11. The electronic device according to claim 10 wherein the adjustable voltage source has an output voltage range which is adjustable in voltages steps, and is configured such that each output voltage of the output voltage range is selectable based on the stored information.

12. The electronic device of claim 10 wherein the adjustable voltage source comprises:
a digital-to-analog converter having:
an operational amplifier;
a resistor ladder comprising a series connection of a number of resistors, a first end of the resistor ladder being connected with an output of the operational amplifier, a second end of the resistor ladder being connected to ground, and one of the interconnection points between the resistors of the resistor ladder being connected to an inverting input of operational amplifier such as to form a non-inverting amplifier configuration; and
a switch configured to selectively connect one of the interconnection points of the resistor ladder to an output of the adjustable voltage source.

13. The electronic device according to claim 8 wherein the stored information on the at least one offset-voltage and the at least one temperature related parameter are respective binary coded information.

14. The electronic device according to claim 2, further comprising:
a voltage adder configured to add the at least one offset voltage to the low-voltage to produce the reference voltage.

15. The electronic device of clam 14 wherein the voltage adder comprises:
an operational amplifier section having an inverting input and a non-inverting input, an output for outputting an output voltage, and a feedback resistor connected to the inverting input and the output of the operational amplifier, wherein the at least one offset voltage is applied to the non-inverting input of operational amplifier, and the low voltage is generated as voltage drop over the feedback resistor by a respective current such that a sum of the at least one offset voltage and the low voltage appears at the output of the operational amplifier.

16. The electronic device according to claim 1, further comprising:
a supply voltage source configured to provide a controlled supply voltage for the semiconductor circuit based on the reference voltage.

17. A testing unit, comprising:
an adjustable offset voltage source having an offset voltage terminal configured to supply an offset voltage; and
a controller configured to interface with semiconductor circuitry and an electronic circuit, to control a test of the semiconductor circuitry in a closed-loop configuration to determine a minimal supply voltage for the semiconductor circuitry at a testing temperature such that operating specifications of the semiconductor circuitry are met, and to store information in the electronic circuit indicative of at least one offset voltage and at least one temperature dependent parameter which correspond to the minimal supply voltage at the testing temperature, wherein in the closed-loop configuration the testing unit is coupled to the electronic circuit via the offset voltage terminal and via the semiconductor circuitry, and the testing unit is configured to receive information on the test and to adjust the offset voltage until the test is passed, thereby determining the minimal supply voltage.

18. A method, comprising:
during fabrication of a semiconductor circuit,
determining information related to at least one offset voltage and at least one temperature-related parameter, which identify a minimal supply voltage for the semiconductor circuit at a testing temperature satisfying a testing criteria of the semiconductor circuit; and
storing the information related to the at least one offset voltage and the at least one temperature-related parameter in a memory of the semiconductor circuit.

19. The method according to claim 18 wherein the step of determining comprises:
selecting a low-voltage source with a temperature coefficient corresponding to the at least one temperature-related parameter, the low-voltage source providing a temperature proportional low-voltage;
adding the at least one offset voltage to the low-voltage to produce a reference voltage; and
generating a corresponding supply voltage for the semiconductor circuit based on the reference voltage.

20. The method according to claim 18 wherein the step of determining is performed in a closed-loop configuration and comprises producing of the reference voltage and generating the supply voltage by adjusting the offset voltage until a test for the semiconductor circuit is passed.

21. The method according to claim 18 wherein the step of storing information related to the at least one offset voltage and the at least one temperature related parameter comprises:
storing parameter values for identifying a selected low-voltage source and the offset voltage.

22. The method according to claim 18 wherein the testing temperature is an arbitrary temperature, which is higher than a normal ambient temperature.

23. The method of claim 22 wherein the arbitrary temperature is less than a maximum allowable temperature of the semiconductor circuit.

24. The method according to claim 19 wherein the step of determining comprises:
outputting the reference voltage to a testing unit;
generating the supply voltage based on the reference voltage; and
supplying the generated supply voltage to the semiconductor circuit through one of the testing unit or a separate voltage supply unit.

25. The method according to claim 19 wherein the step of generating the supply voltage for the semiconductor circuitry based on the reference voltage comprises:
multiplying the produced reference voltage by a control factor.

26. A method, comprising:
reading from a memory stored information related to at least one offset voltage and at least one temperature-related parameter, which identify a minimal test supply voltage of a semiconductor circuit, measured and stored during production of the semiconductor circuit at a testing temperature; and
generating a minimal operational supply voltage for the semiconductor circuitry based on an actual temperature in an application and the stored information.

27. The method according to claim 26 wherein the step of reading stored information related to the at least one offset voltage and the at least one temperature related parameter comprises retrieving parameter values for identifying a low-voltage source with a temperature coefficient corresponding to the at least one temperature-related parameter and the offset voltage, and the method further comprises:
adding the offset voltage to a low-voltage provided by the low-voltage source to produce a reference voltage.

28. The method according to claim 27 wherein the minimal test supply voltage corresponds to a voltage at which a testing criteria is satisfied and the step of generating the minimal operational supply voltage comprises:
minimizing the reference voltage in an open-loop configuration by adjusting the low-voltage based on a difference between the actual temperature in the application and the testing temperature in production.

29. The method according to claim 28 wherein the step of generating the minimal operational supply voltage further comprises:
applying the reference voltage to an on-chip or off-chip power management unit for generating the minimal operational supply voltage and supplying the minimal operational supply voltage to the semiconductor circuitry.

30. The method according to claim 29 wherein the minimal operational supply voltage is equal to the minimal test supply voltage when the actual temperature is equal to the testing temperature.

31. A system, comprising:
semiconductor circuitry;
an electronic circuit having a memory configured to store information related to at least one offset voltage and at least one temperature-related parameter, which identify a minimal supply voltage for the semiconductor circuitry at a testing temperature, and a reference voltage generator configured to produce a reference voltage corresponding to the minimal supply voltage at the testing temperature; and
a testing unit configured to:
determine the minimal supply voltage for the semiconductor circuitry at the testing temperature in a closed-loop configuration such that a test for the semiconductor circuitry is passed; and
store the information related to the minimal supply voltage into the memory together with the at least one temperature-related parameter wherein the testing unit is connectable to the electronic circuit and the semiconductor circuitry in the closed-loop configuration, and the testing unit is configured to control the test for the semiconductor circuitry, to select the at least one temperature-related parameter and to adjust the at least one offset voltage of the reference voltage until the test for the semiconductor circuitry is passed, thereby determining the minimal supply voltage.

32. A system, comprising:
semiconductor circuitry;
an electronic circuit having a memory configured to store information related to at least one offset voltage and at least one temperature-related parameter, which identify a minimal supply voltage for the semiconductor circuitry at a testing temperature and a reference voltage generator configured to produce a reference voltage comprised of the at least one offset voltage and a variable voltage which is based on the at least one temperature-related parameter and a difference between an actual temperature and the testing temperature; and
a power management unit generate a minimal operational supply voltage for the semiconductor circuitry based on the reference voltage, wherein the power management unit is connected with the electronic circuit and the semiconductor circuitry in a open-loop configuration.

33. A system, comprising:
semiconductor circuitry;
means for storing information related to at least one offset voltage and at least one temperature-related parameter, which identify a minimal supply voltage for the semiconductor circuitry at a testing temperature;
means for generating a reference voltage comprised of the at least one offset voltage and a variable voltage which is based on the at least one temperature-related parameter and a difference between an actual temperature and the testing temperature; and
means for generating a minimal operational supply voltage for the semiconductor circuitry in an open-loop configuration based on the reference voltage.
